(19) United States
(12) Patent Application Publication
(10) Pub. No.: US 2021/0296294 A1
(43) Pub. Date: Sep. 23, 2021

(54) PACKAGING BODY AND PREPARATION METHOD THEREFOR

(71) Applicant: DURA-CHIP (NANTONG) LIMITED, Nantong (CN)

(72) Inventors: Zhijiang SUN, Nantong (CN); Shuchang WANG, Nantong (CN); Lu WU, Nantong (CN)

(21) Appl. No.: 17/339,944

(22) Filed: Jun. 5, 2021

Related U.S. Application Data
(63) Continuation of application No. PCT/CN2019/123375, filed on Dec. 5, 2019.

(30) Foreign Application Priority Data
Dec. 7, 2018 (CN) 201811495570.7
Jul. 16, 2019 (CN) 201910639825.0
Jul. 16, 2019 (CN) 201910639866.X
Jul. 16, 2019 (CN) 201910640049.6
Nov. 20, 2019 (CN) 201911139025.9
Nov. 29, 2019 (CN) 201922104657.3

(51) Int. Cl. H01L 25/075; H01L 21/66

(52) U.S. Cl. CPC H01L 25/0753; A01G 7/045; H01L 22/22

(57) ABSTRACT

The present disclosure provides a packaging body and a preparation method thereof. The packaging body comprises a support member; at least one first chip and at least one second chip, the first chip and the second chip being located on a side surface of the support member, and at least the top surface in the surfaces of the second chip being provided with a long-wavelength phosphor adhesive layer; and a packaging layer covering the side of the support member provided with the first chip and the second chip. The first chip, the second chip, and the long-wavelength phosphor adhesive layer are located in the packaging layer, and the packaging layer is formed by a first wavelength phosphor adhesive layer that does not contain long-wavelength phosphor. The peak wavelength L1 of phosphor in the first wavelength phosphor adhesive layer is less than the peak wavelength L_{red} of the long-wavelength phosphor.

### CROSS REFERENCE TO RELATED APPLICATIONS

This application is a continuation of international application No. PCT/CN2019/123375 filed on Dec. 5, 2019, and titled “PACKAGING BODY AND PREPARATION METHOD THEREOF” in the China National Intellectual Property Administration, the content of which is hereby incorporated by reference.

### TECHNICAL FIELD

The present disclosure relates to semiconductor optoelectronics and optics fields, and in particular, to a packaging body and a method for preparing the same.

### BACKGROUND

Currently, white LEDs can be prepared by the following methods. In a first method, referring to curve (1) in FIG. 1, a white light can be obtained by exciting a pure yellow phosphor by a blue light. In this case, the luminous efficiency is generally higher, but the color rendering index is only about 70, and it is not suitable to be used in scenarios requiring lower color temperatures. When applied in scenarios requiring lower color temperatures, a red phosphor can be added. Furthermore, if the color rendering index is required to be over 80, the red phosphor and a green phosphor can be simultaneously added. Referring to curve (2) in FIG. 1, when the red phosphor and the green phosphor are added at the same time, the color rendering index can reach 80. However, it can be concluded from the curve (2) in FIG. 1, in scenarios requiring full spectrum, the spectrum lacks blue light and cyan light with wavelengths in the range of 460 nm to 510 nm. Therefore, cyan phosphor having a peak wave length in a range of 470 nm to 505 nm can be added in scenarios requiring full spectrum.

In a conventional method, a blue light chip is used to excite a mixed phosphor to provide a full spectrum. However, the white light obtained by this method cannot meet requirements of high luminous efficiency and high color rendering index. Therefore, it is necessary to provide a new packaging body to improve luminous efficiency and color rendering index of a light source.

### SUMMARY

In the present disclosure, a packaging body and a method for preparing the same are provided. The packaging body in the present disclosure has a greater color rendering index and better luminous efficiency.

In order to solve the technical problems above, the present disclosure provides a technical solution which provides a packaging body. The packaging body includes: a support member; at least one first chip and at least one second chip, the at least one first chip and the at least one second chip being located on a surface of the support member, and at least a top surface of the at least one second chip being provided with a long-wavelength phosphor adhesive layer; and, a packaging layer covering the surface of the support member. The at least one first chip, the at least one second chip, and the long-wavelength phosphor adhesive layer are located in the packaging layer. The packaging layer is a first phosphor adhesive layer that does not contain a long-wavelength phosphor. A peak wavelength L₁ of emitting light of a phosphor in the first phosphor adhesive layer is less than a peak wavelength L_{red} of emitting light of the long-wavelength phosphor.

In order to solve the technical problems above, the present disclosure provides another technical solution which provides a method for preparing a packaging body. The method for preparing the packaging body includes the following steps:

step S1, providing at least one first chip and at least one second chip, wherein a long-wavelength phosphor adhesive layer is disposed on at least a top surface of the at least one second chip;

step S2, designing a ratio of a number of the at least one second chip to a total number of the at least one first chip and the at least one second chip according to a preset color temperature of a packaging body product, defining a chromaticity coordinate of the at least one second chip on a CIE chromaticity diagram according to the ratio of the number of the at least one second chip to the total number of the at least one first chip and the at least one second chip as a red point (X1, Y1), and defining a chromaticity coordinate of the at least one first chip on the CIE chromaticity diagram according to the ratio of the number of the at least one first chip to the total number of the at least one first chip and the at least one second chip as a blue point (X2, Y2);

step S3, pre-controlling the color temperature:

fixing the at least one first chip and the at least one second chip to corresponding positions on a support member, respectively;

making the at least one first chip and the at least one second chip emit light, and looking up a chromaticity coordinate of the lighted at least one first chip and the lighted least one second chip on the CIE chromaticity diagram, wherein the chromaticity coordinate of the lighted at least one first chip and lighted least one second chip is identified as a mixed point (X3, Y3);

ensuring that the Y3 in mixed point (X3, Y3) is greater than or equal to 0.08 and less than or equal to 0.30, and the X3 in mixed point (X3, Y3) is greater than or equal to 0.22 and less than or equal to 0.43, thereby pre-controlling a range of the color temperature; and

if the Y3 in mixed point (X3, Y3) is not greater than or equal to 0.08 and less than or equal to 0.30, and the X3 in mixed point (X3, Y3) is not greater than or equal to 0.22 and less than or equal to 0.43, repeating step S2;

step S4, looking up a chromatic coordinate of the preset color temperature of the packaging body product along the Planckian locus on the CIE chromaticity diagram according to requirements of the present color temperature of the packaging body product, and identifying the chromaticity coordinate of the preset color temperature of the packaging body product as a white point (X4, Y4); obtaining a specific chromatic coordinate or a range of chromatic coordinates of a green point (X5, Y5) according to chromatic coordinates of the red point (X1, Y1), the blue point (X2, Y2), the mixed point (X3, Y3) and the white point (X4, Y4); selecting a suitable first phosphor according to the chromatic coordinate of the green point, and mixing the first phosphor with a glue to form a first phosphor adhesive layer; entirely packaging the at least one first chip and the at least one second chip on the supporting member with the first phosphor adhesive layer to form a packaging layer; and heating and solidifying to obtain the packaging body product; and

step S5, detecting a luminescence spectrum and the color temperature of the packaging body product,

wherein if a chromatic coordinate of the packaging body product is different from that along the Planckian locus, adjusting constituents of the first phosphor in the packing layer;

if the color temperature does not conform to the preset color temperature, adjusting the ratio of the number of the at least one second chip to the total number of the at least one first chip and the at least one second chip, and repeating the steps S3 to S5.

In order to solve the technical problems above, the present disclosure provides another technical solution which provides a packaging body. The packaging body includes: a support member; at least one first chip and at least one second chip, wherein the at least one first chip and the least one second chip are located on a surface of the support member, and at least a top surface of the least one second chip is provided with a blue phosphor adhesive layer; and, a packaging layer covering the surface of the support member. The at least one first chip, the least one second chip, and the blue phosphor adhesive layer are located in the packaging layer. The packaging layer is a first phosphor adhesive layer that does not contain a blue phosphor. A peak wavelength L₁ of a phosphor in the first phosphor adhesive layer is greater than a peak wavelength L_{blue} of the blue phosphor in the blue phosphor adhesive layer.

Compared with conventional art, the present disclosure has the following advantages. Firstly, chips having different emission wavelengths are used, so therefore phosphors having different excitation wavelengths can be excited. That is, a short-wavelength fluorescence emitted from a short-wavelength chip can excite a short-wavelength phosphor, and a long-wavelength fluorescence emitted from a long-wavelength chip can excite a long-wavelength phosphor. Meanwhile, a short-wavelength fluorescence emitted by the short-wavelength phosphor will not excite the long-wavelength phosphor and be consumed again. Therefore, optimal quantum yield can be achieved and luminous efficiency of a light source can be improved via choosing an optimal excitation wavelength. Secondly, chips having different emission wavelengths are packaged by different methods, respectively. Compared with the conventional art, the long-wavelength phosphor is packaged in local areas such as a top surface and sidewalls of a chip by CSP method or WLP method, and only a small amount of short-wavelength fluorescence and medium-wavelength fluorescence can illuminate on the long-wavelength phosphor. This can effectively prevent cyan fluorescence, blue fluorescence and green fluorescence from being absorbed again by the long-wavelength phosphor. For cyan light having low excitation efficiency, the method in the present disclosure can effectively reduce secondary loss of cyan fluorescence and improve the luminous efficiency while improving color rendering index. Thirdly, according to Stokes shift, for one phosphor, a wavelength of an emitting light will shift along with shift of a wavelength of an excitation light. Therefore, in the present disclosure, a red fluorescence having a relatively long wavelength can be obtained by exciting a long-wavelength phosphor with a long-wavelength fluorescence emitted by a long-wavelength chip. Similarly, a cyan fluorescence having a relatively short wavelength can be obtained by exciting a cyan phosphor with a short-wavelength fluorescence emitted by a short-wavelength chip; a blue fluorescence having a relatively short wavelength can be obtained by exciting a blue phosphor with a short-wavelength fluorescence emitted by a short-wavelength chip; and a green fluorescence having a relatively short wavelength can be obtained by exciting a green phosphor with a short-wavelength fluorescence emitted by a short-wavelength chip. Therefore, a fluorescence band spectrum of a packaging body can be broader, and the color rendering index can be further improved. Fourthly, in the present disclosure, a color temperature of the packaging body can be adjusted by changing a ratio of a number of a red chip to a number of a blue chip. In conventional art, the color temperature of a light source is changed by adjusting an amount of a red phosphor or other phosphors in the entire phosphor layer, but this may result in an emitting surface packaged by COB method being dark and turbid. Besides, in a conventional art, the phosphor needs to be accurately weighted with a high precision balance to change the color temperature. However, in the present disclosure, the chips are packaged by CSP method, respectively. Therefore, the color temperature can be changed by adjusting the ratio of the number of the red chips to the number of the blue chips.

### BRIEF DESCRIPTION OF THE DRAWINGS

FIG. 1 is a luminescence spectrum diagram of an embodiment of a conventional white LED.

FIG. 2 is a structural schematic diagram of a packaging body in an embodiment of the present disclosure.

FIG. 3 is a structural schematic diagram of a packaging body in another embodiment of the present disclosure.

FIG. 4 is a structural schematic diagram of an excitation mode of the packaging body in FIG. 2.

FIG. 5 is a top view of a packaging body in an embodiment of the present disclosure.

FIG. 6 is a structural schematic diagram of a packaging body in another embodiment of the present disclosure.

FIG. 7 is a structural schematic diagram of a packaging body in another embodiment of the present disclosure.

FIG. 8 is a structural schematic diagram of an excitation mode of the packaging body in FIG. 6.

FIG. 9 is a structural schematic diagram of a packaging body in another embodiment of the present disclosure.

FIG. 10 is a structural schematic diagram of a packaging body in another embodiment of the present disclosure.

FIG. 11 is a structural schematic diagram of an excitation mode of the packaging body in FIG. 9.

FIG. 12 is a structural schematic diagram of a packaging body in another embodiment of the present disclosure.

FIG. 13 is a structural schematic diagram of a packaging body in another embodiment of the present disclosure.

FIG. 14 is a structural schematic diagram of an excitation mode of the packaging body in FIG. 13.

FIG. 15 is a structural schematic diagram of a packaging body in another embodiment of the present disclosure.

FIG. 16 is a structural schematic diagram of a packaging body in another embodiment of the present disclosure.

FIG. 17 is a structural schematic diagram of a packaging body in another embodiment of the present disclosure.

FIG. 18 is a spectrum diagram of an example of embodiment 1.

FIG. 19 is a spectrum diagram of an example of embodiment 2.

FIG. 20 is a spectrum diagram of an example of embodiment 3.

FIG. 21 is a spectrum diagram of an example of embodiment 4.

FIG. 22 is a spectrum diagram of an example of embodiment 5.

FIG. 23 is a spectrum diagram of an example of embodiment 6.

FIG. 24 is a spectrum diagram of an example of embodiment 7.

FIG. 25 is a spectrum diagram of an example of embodiment 8.

FIG. 26 is a spectrum diagram of an example of embodiment 9.

FIG. 27 is a spectrum diagram of an example of embodiment 10.

FIG. 28 is a spectrum diagram of an example of embodiment 11.

FIG. 29 is a structural schematic diagram of a packaging body in another embodiment of the present disclosure.

FIG. 30 is a structural schematic diagram of an excitation mode of the packaging body in FIG. 29.

### DETAILED DESCRIPTION

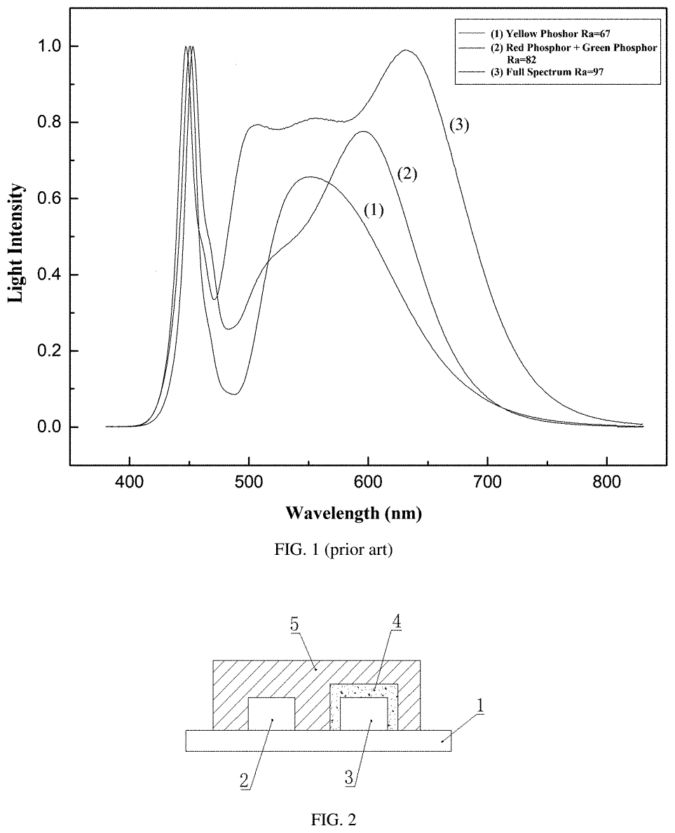

Referring to FIG. 2, FIG. 2 is a structural schematic diagram of a packaging body in an embodiment of the present disclosure. The packaging body can include: a support member 1, wherein the support member 1 can be any one selected from a substrate with a circuit, a support frame with a circuit and an adhesive membrane without a circuit; at least one first chip 2 and at least one second chip 3, the at least one first chip 2 and the at least one second chip 3 being located on a surface of the support member 1, and at least a top surface of the at least one second chip being provided with a long-wavelength phosphor adhesive layer 4 (i.e., a red phosphor adhesive layer); and, a packaging layer 5 covering the surface of the support member 1, wherein the at least one first chip 2, the at least one second chip 3, and the long-wavelength phosphor adhesive layer 4 can be located in the packaging layer 5. The packaging layer 5 can be a first phosphor adhesive layer that does not contain a long-wavelength phosphor. A peak wavelength L₁ of emitting light of a phosphor in the first phosphor adhesive layer is less than a peak wavelength L_{red} of emitting light of the long-wavelength phosphor.

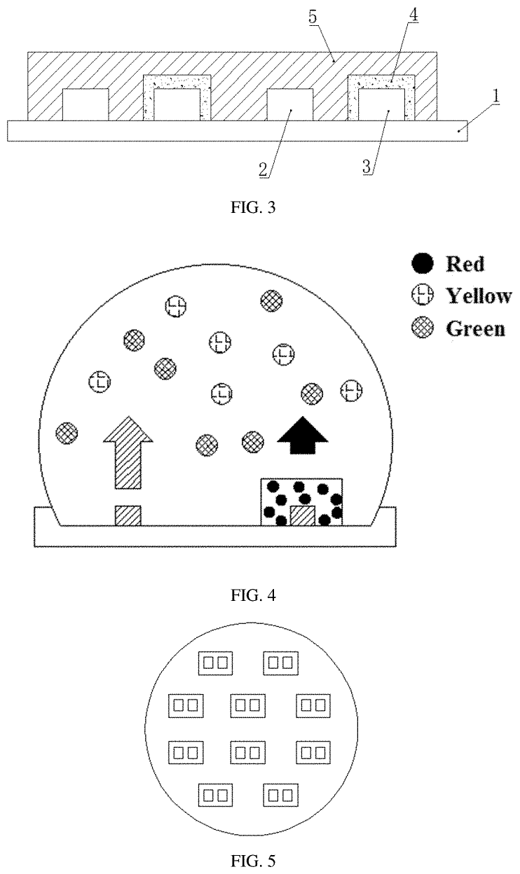

It should be noted that only one first chip 2 and one second chip 3 are schematically shown in FIG. 2. In some embodiments, referring to FIG. 3, the number of the first chips 2 and the number of the second chips 3 can be increased according to requirements of an actual luminescence spectrum.

In some embodiments, a peak wavelength of emitting light of the at least one first chip 2 can be identified as λA, in a range of 390 nm to 460 nm. A peak wavelength of emitting light of the at least one second chip 3 can be identified as λB, which can be in a range of 445 nm to 550 nm. The peak wavelength λA of emitting light of the at least one first chip 2 and the peak wavelength λB of emitting light of the at least one second chip 3 satisfy a formula as follow: 0≤λB−λA≤160 nm. In some embodiments, the phosphor in the first phosphor adhesive layer of the packaging layer 5 can be one or more selected from a green phosphor, an indigo phosphor, a cyan phosphor, a yellow phosphor and a blue phosphor, and the peak wavelength L₁ of emitting light of the phosphor in the first phosphor adhesive layer can be in a range of 470 nm to 590 nm.

FIG. 4 is a structural schematic diagram of an excitation mode of the packaging body in the present embodiment. Some technical solutions of the present embodiment are illustrated herein after.

Referring to FIG. 5, FIG. 5 is a top view of a packaging body in an embodiment of the present disclosure. Taking a packaging body packaged by a COB method for an example, the method for preparing the packaging body can include following steps: hardening a first chip 2 and a second chip 3 on a support member 1 having a circuit, wherein the support member 1 can be a substrate; applying a glue on the substrate to form a circle-shaped area or a square-shaped area on the substrate; then coating a phosphor adhesive layer in entire to form an integrated COB packaging structure. The packaging body can further be prepared by a SMD method, a CSP method or a lamp filament according to actual requirement. The packaging body of the present disclosure will be further illustrated in conjunction with some embodiments. In the present embodiment, the long-wavelength phosphor adhesive layer 4 can be disposed on both a top surface of the second chip 3 and sidewalls of the second chip 3. Three samples of the packaging body of the present disclosure are described in detail hereinafter.

In a sample of the packaging body denoted as HDK-S1-1, a first chip 2 was an LED chip which emitted a light having a peak wavelength of 445 nm; a second chip 3 was an LED chip which emitted a light having a peak wavelength of 450 nm; a phosphor in the long-wavelength phosphor adhesive layer 4 was a red phosphor; and a phosphor in the first phosphor adhesive layer, that did not contain the red phosphor of the packaging layer 5, was a mixed phosphor containing a green phosphor and a yellow phosphor; wherein a peak wavelength of emitting light of the mixed phosphor was 510 nm.

In a sample of the packaging body denoted as HDK-S1-2, a first chip 2 was an LED chip which emitted a light having a peak wavelength of 445 nm; a second chip 3 was an LED chip which emitted a light having a peak wavelength of 445 nm; a phosphor in the long-wavelength phosphor adhesive layer 4 was a red phosphor; and a phosphor in the first phosphor adhesive layer, that did not contain the red phosphor of the packaging layer 5, was a mixed phosphor containing a green phosphor and a yellow phosphor; wherein a peak wavelength of emitting light of the mixed phosphor was 510 nm.

In a sample of the packaging body denoted as HDK-S1-3, a first chip 2 was an LED chip which emitted a light having a peak wavelength of 420 nm; a second chip was 3 an LED chip which emitted a light having a peak wavelength of 445 nm; a phosphor in the long-wavelength phosphor adhesive layer 4 was a red phosphor; and a phosphor in the first phosphor adhesive layer, that did not contain the red phosphor of the packaging layer 5, was a mixed phosphor containing a green phosphor and a yellow phosphor; wherein a peak wavelength of emitting light of the mixed phosphor was 510 nm.

The three samples and a packaging body product purchased from the market were tested, and average values of the tests were shown in Table 1 hereinafter.

TABLE 1
test results of the packaging body product purchased from the market and three samples of the present disclosure

| | Number | Forward | Forward | Power | Luminous | Luminous | Color | Color | Chromaticity | Chromaticity |
|---|---|---|---|---|---|---|---|---|---|---|
| | of the | current | Voltage | P | Flux | Efficiency | Temperature | Rendering | Coordinate | Coordinate |
| Sample | sample | I_{F} (mA) | V_{F} (V) | (W) | Φ(lm) | (lm/W) | (K) | Index | X | Y |
| A | 8 | 260 | 130 | 33.8 | 3447 | 102 | 5043 | 90 | 0.4316 | 0.3945 |
| product | | | | | | | | | | |
| of DY | | | | | | | | | | |
| HDK- | 12 | 260.4 | 139.7 | 36.38 | 4365 | 120 | 3000 | 90 | 0.4394 | 0.4083 |
| S1-1 | | | | | | | | | | |
| HDK- | 12 | 260.4 | 139.8 | 36.40 | 4259 | 117 | 3000 | 90 | 0.4358 | 0.4096 |
| S1-2 | | | | | | | | | | |
| HDK- | 12 | 260.4 | 140.1 | 36.48 | 4086 | 112 | 3000 | 90 | 0.439 | 0.4087 |
| S1-3 | | | | | | | | | | |

It can be concluded from Table 1 that, when the peak wavelength of emitting light of the second chip 3 is not less than the peak wavelength of emitting light of the first chip 2, the luminous efficiency of the second chip 3 can be further improved.

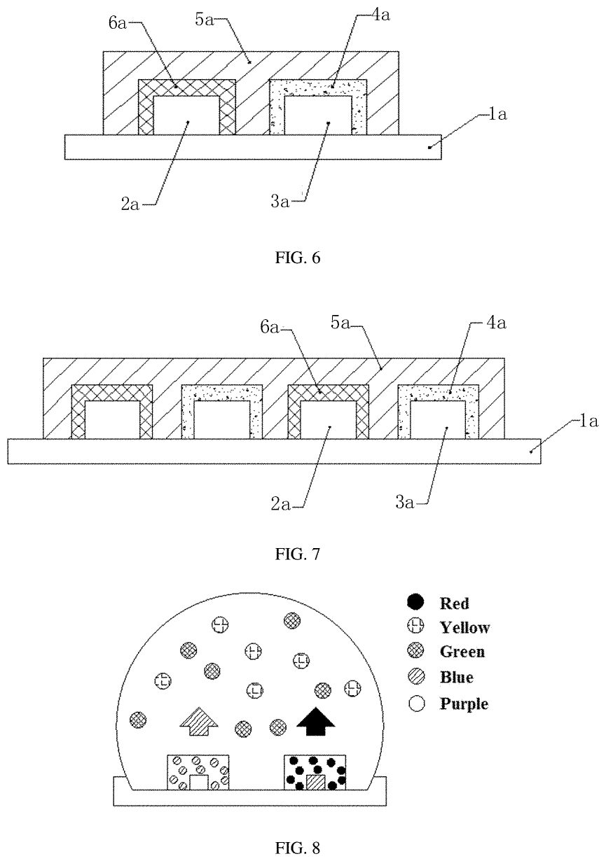

In another embodiment, referring to FIG. 6, at least the top surface of the first chip 2a can be provided with a second phosphor adhesive layer 6a that does not contain a red phosphor. The second phosphor adhesive layer 6a can be located in the packaging layer 5a. A peak wavelength L₂ of a phosphor in the second phosphor adhesive layer 6a can be less than the peak wavelength L₁ of emitting light of the phosphor in the first phosphor adhesive layer in the packaging layer 5a. That is, in the present embodiment, the peak wavelength L₁ of emitting light of the phosphor in the first phosphor adhesive layer and the peak wavelength L₂ of the phosphor in the second phosphor adhesive layer 6a can satisfy a formula as follows: L₂<L₁<L_{red}, wherein L_{red} is a peak wavelength of emitting light of red phosphor.

It should be noted that only one first chip 2a and one second chip 3a are schematically shown in FIG. 6. In some embodiments, referring to FIG. 7, the number of the first chips 2a and the number of the second chips 3a can be increased according to requirements of an actual luminescence spectrum.

In the present embodiment, a peak wavelength of emitting light of the at least one first chip can be identified as λA, and in a range of 390 nm to 445 nm. A peak wavelength of emitting light of the at least one second chip can be identified as λB, and in a range of 445 nm to 550 nm. The peak wavelength λA of emitting light of the at least one first chip and the peak wavelength λB of emitting light of the at least one second chip can satisfy a formula as follow: 5≤λB−λA≤160 nm. In some embodiments, the phosphor in the first phosphor adhesive layer can be one or more selected from a green phosphor and a yellow phosphor, and the peak wavelength L₁ of emitting light of the phosphor in the first phosphor adhesive layer can be in a range of 510 nm to 590 nm. The phosphor in the second phosphor adhesive layer can be one or more selected from a green phosphor, an indigo phosphor, a cyan phosphor, a yellow phosphor and a blue phosphor, and peak wavelength L₂ of a phosphor in the second phosphor adhesive layer can be in a range of 470 nm to 590 nm.

Referring to FIG. 8, FIG. 8 is a structural schematic diagram of an excitation mode of the packaging body in the present embodiment. Some packaging bodies of the present embodiment were packaged by an SMD method and tested. A long-wavelength phosphor adhesive layer 4a was disposed on both a top surface of the second chip 3a and sidewalls of the second chip 3a. A second phosphor adhesive layer 6a that did not contain a red phosphor was disposed on a top surface and sidewalls of the first chip 2a. Three samples of the packaging body of the present disclosure were described in detail hereinafter.

In a sample of the packaging body denoted as HDK-S2-1, a first chip 2a was an LED chip which emitted a light having a peak wavelength of 445 nm; a second chip 3a was an LED chip which emitted a light having a peak wavelength of 455 nm; a phosphor in the long-wavelength phosphor adhesive layer 4a was a red phosphor; a phosphor in the packaging layer 5a was a mixed phosphor of a yellow phosphor and a green phosphor which emitted a light having a peak wavelength of 520 nm; and a phosphor in the second phosphor adhesive layer 6a, that did not contain the red phosphor, was a mixed phosphor containing a blue phosphor; wherein a peak wavelength of emitting light of the blue phosphor was 475 nm.

In a sample of the packaging body denoted as HDK-S2-2, a first chip 2a was an LED chip which emitted a light having a peak wavelength of 445 nm; a second chip 3a was an LED chip which emitted a light having a peak wavelength of 450 nm; a phosphor in the long-wavelength phosphor adhesive layer 4a was a red phosphor; a phosphor in the packaging layer 5a was a mixed phosphor of a yellow phosphor and a green phosphor which emitted a light having a peak wavelength of 520 nm; and a phosphor in the second phosphor adhesive layer 6a, that did not contain the red phosphor, was a mixed phosphor containing a blue phosphor; wherein a peak wavelength of emitting light of the blue phosphor was 475 nm.

In a sample of the packaging body denoted as HDK-S2-3, a first chip 2a was an LED chip which emitted a light having a peak wavelength of 445 nm; a second chip 3a was an LED chip which emitted a light having a peak wavelength of 445 nm; a phosphor in the long-wavelength phosphor adhesive layer 4a was a red phosphor; a phosphor in the packaging layer 5a was a mixed phosphor of a yellow phosphor and a green phosphor which emitted a light having a peak wavelength of 520 nm; and a phosphor in the second phosphor adhesive layer 6a, that did not contain the red phosphor, was a mixed phosphor containing a blue phosphor; wherein a peak wavelength of emitting light of the blue phosphor was 475 nm.

The three samples and a packaging body product purchased from the market were tested, and average values of the tests were shown in Table 2 hereinafter.

TABLE 2
test results of products purchased from the market and three samples of the present disclosure

| | Forward | Forward | Power | Luminous | Luminous | Chromaticity | Chromaticity | Color |
|---|---|---|---|---|---|---|---|---|
| | current | Voltage | P | Flux | Efficiency | Coordinate | Coordinate | Temperature |
| Sample | I_{F} (mA) | V_{F} (V) | (W) | Φ(lm) | (lm/W) | X | Y | Tc (K) |
| A Chip of | 149.9 | 3.31 | 496.3 | 51.5 | 103.81 | 0.3293 | 0.3364 | 5644 |
| SEOUL | | | | | | | | |
| A Chip of | 149.9 | 3.24 | 485.6 | 50.4 | 103.79 | 0.3438 | 0.3494 | 5043 |
| SEOUL | | | | | | | | |
| HDK-S2-1 | 59.9 | 8.763 | 525 | 46.8 | 138.67 | 0.3802 | 0.3784 | 4017 |
| HDK-S2-2 | 59.9 | 8.805 | 527 | 45.8 | 127.18 | 0.3774 | 0.3762 | 4078 |
| HDK-S2-3 | 59.9 | 8.832 | 529 | 55.6 | 105.13 | 0.3677 | 0.3883 | 4427 |

It can be concluded from Table 2 that when the light source areas of the samples were the same, the light source of the present embodiment had higher luminous efficiency. On the basis that the peak wavelength λA of emitting light of the first chip 2a and the peak wavelength λB of emitting light of the second chip can satisfy the formula as follow: 5≤λB−λA≤160 nm, the luminous efficiency can be further improved.

It should be noted that the high-color rendering index and high luminous efficiency packaging body in the present embodiment was packaged by a SMD method. The first chip 2a and the second chip 3a were flip chips. In actual use, the packaging body is not limited to be packaged by SMD method, but can be packaged by methods such as a COB method, a CPS method, lamp filament method and the like. In embodiments that the packaging body was packaged by the COB method or lamp filament method, the first chip 2a can be a flip chip or a vertical structure chip, and the second chip 3a can be a normal chip.

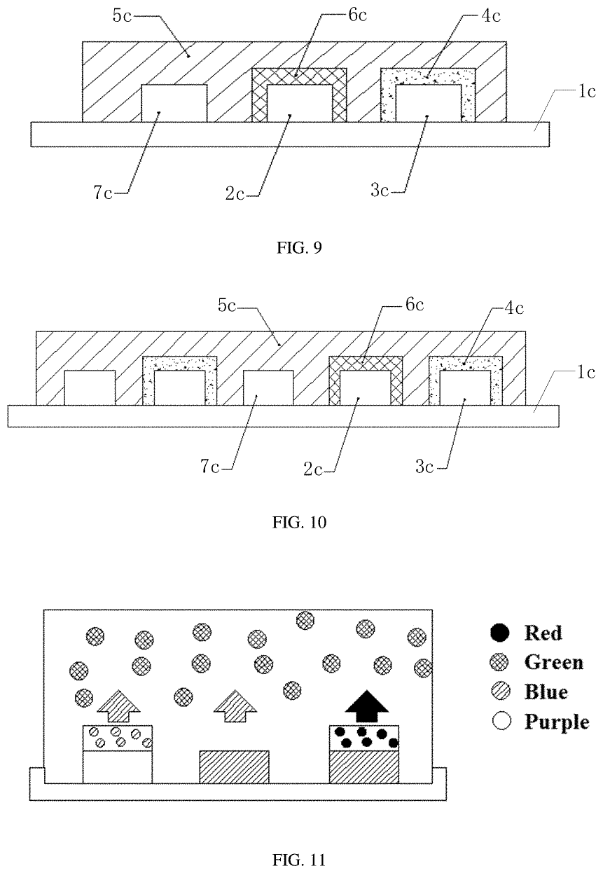

Furthermore, in some embodiments, referring to FIG. 9, at least one third chip 7c can be disposed at the surface disposing the first chip 2c of the supporting member 1c. A peak wavelength of emitting light of the at least one first chip can be identified as λA, which can be in a range of 390 nm to 445 nm. A peak wavelength of emitting light of the third chip 7c can be identified as λC, which can be in a range of 420 nm to 465 nm. A peak wavelength of emitting light of the at least one second chip can be identified as λB, which can be in a range of 445 nm to 550 nm. The peak wavelength λA of emitting light of the first chip 2c, the peak wavelength λC of emitting light of the third chip 7c and the peak wavelength of emitting light λB of the second chip 3c can satisfy formulas as follow: 0≤λB−λC≤130 nm and 15≤λC−λA≤130 nm.

It should be noted that a number of the first chips 2c, a number of the chips 3c and a number of the third chips 7c are not limited to those shown in FIG. 9. In some embodiments, referring to FIG. 10, the number of the first chips 2c, the number of the third chips 7c and the number of the second chips 3c can be increased according to requirements of an actual luminescence spectrum.

In the present embodiment, the first chip 2c can be a purple LED chip which emits light having a peak wavelength in a range of 390 nm to 430 nm. The phosphor in the first phosphor adhesive layer of the packaging layer 5c can be one or more selected from a green phosphor, and a yellow phosphor. The peak wavelength L₁ of emitting light of the phosphor in the first phosphor adhesive layer can be in a range of 510 nm to 590 nm. The phosphor in the second phosphor adhesive layer 6c can be one or more selected from an indigo phosphor, a cyan phosphor and a blue phosphor, and the peak wavelength L₂ of a phosphor in the second phosphor adhesive layer 6c can be in a range of 470 nm to 510 nm.

The first chip 2c, the second chip 3c and the third chip 4c can be normal chips, flip chips or vertical structure chips. In some embodiments, the first chip 2c can be the flip chip or the vertical structure chip, and the second chip 3c and the third chip 4c can be normal chips.

Referring to FIG. 11, FIG. 11 is a structural schematic diagram of an excitation mode of the packaging body the present embodiment. In the present embodiment, the packaging bodies were packaged by lamp filament method and tested. In the samples, a long-wavelength phosphor adhesive layer 4c was merely disposed on a top surface of the second chip 3c, and a second phosphor adhesive layer, that did not contain a red phosphor, was merely disposed on a top surface of the first chip 2c. The three samples of the packaging body were disposed in detail hereinafter.

In a sample of the packaging body denoted as HDK-S4-1, a first chip 2c was an LED chip which emitted a light having a peak wavelength of 430 nm; a third chip 7c was an LED chip which emitted a light having a peak wavelength of 455 nm; a second chip 3c was an LED chip which emitted a light having a peak wavelength of 465 nm; a phosphor in the long-wavelength phosphor adhesive layer 4c was a red phosphor; a phosphor 6c was a blue phosphor having a peak wavelength of emitting light of 475 nm; and a phosphor of the of the first phosphor adhesive layer in the packaging layer 5c was a mixed phosphor of a yellow phosphor and a green phosphor having a peak wavelength of emitting light of 530 nm.

In a sample of the packaging body denoted as HDK-S4-2, a first chip 2c was an LED chip which emitted a light having a peak wavelength of 430 nm; a third chip 7c was an LED chip which emitted a light having a peak wavelength of 445 nm; a second chip 3c was an LED chip which emitted a light having a peak wavelength of 445 nm; a phosphor in the long-wavelength phosphor adhesive layer 4c was a red phosphor; a phosphor of the second phosphor adhesive layer 6c was a blue phosphor having a peak wavelength of emitting light of 475 nm; and a phosphor of the first phosphor adhesive layer in the packaging layer 5c was a mixed phosphor of a yellow phosphor and a green phosphor which emitted a light having a peak wavelength of 530 nm.

In a sample of the packaging body denoted as HDK-S4-3, a first chip 2c was an LED chip which emitted a light having a peak wavelength of 430 nm; a third chip 7c was an LED chip which emitted a light having a peak wavelength of 430 nm; a second chip 3c was an LED chip which emitted a light having a peak wavelength of 430 nm; a phosphor in the long-wavelength phosphor adhesive layer 4c was a red phosphor; a phosphor of the second phosphor adhesive layer 6c was a blue phosphor having a peak wavelength of emitting light of 475 nm; and a phosphor of the first phosphor adhesive layer in the packaging layer 5c was a mixed phosphor of a yellow phosphor and a green phosphor which emitted a light having a peak wavelength of 530 nm.

The three samples were tested, and average values of the tests were shown in Table 3 hereinafter.

TABLE 3
test results of three samples of the present disclosure

| | Number | Forward | Forward | Power | Luminous | Luminous | Color | Color | Chromaticity | Chromaticity |
|---|---|---|---|---|---|---|---|---|---|---|
| | of the | current | Voltage | P | Flux | Efficiency | Temperature | Rendering | Coordinate | Coordinate |
| Sample | Samples | I_{F} (mA) | V_{F} (V) | (W) | Φ(lm) | (lm/W) | (K) | Index | X | Y |
| HDK- | 5 | 299 | 18.38 | 5.50 | 758 | 138 | 6500 | 97.4 | 0.3142 | 0.3393 |
| S4-1 | | | | | | | | | | |
| HDK- | 5 | 299 | 18.34 | 5.48 | 740 | 135 | 6500 | 97.6 | 0.3143 | 0.3370 |
| S4-2 | | | | | | | | | | |
| HDK- | 5 | 299 | 18.36 | 5.49 | 703 | 128 | 6500 | 98.7 | 0.3134 | 0.3357 |
| S4-3 | | | | | | | | | | |

In the present embodiment, the chips of the packaging body were packaged by lamp filament method. In some embodiments, the chips can be packaged by SMD method, COB method or CSP method according to actual requirements.

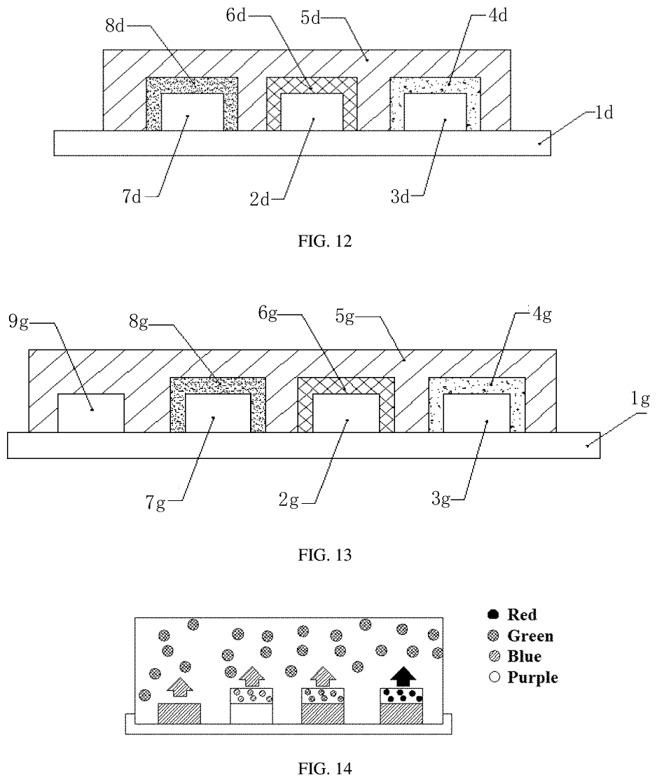

Furthermore, in some embodiments, referring to FIG. 12, at least a top surface of the third chip 7d can be provided with a third phosphor adhesive layer 8d that does not contain a red phosphor, and the third phosphor adhesive layer 7d can be further covered by the packaging layer 5d. In addition, a peak wavelength L₃ of a phosphor in the third phosphor adhesive layer 8d can be greater than the peak wavelength L₂ of emitting light of the phosphor in the second phosphor adhesive layer 6d, and less than the peak wavelength L₁ of emitting light of the phosphor in the first phosphor adhesive layer in the packaging layer 5d. That is, the peak wavelength L₃ of the phosphor in the third phosphor adhesive layer 8d, the peak wavelength L₂ of emitting light of the phosphor in the second phosphor adhesive layer 6d and the peak wavelength L₁ of emitting light of the phosphor in the first phosphor adhesive layer in the packaging layer 5d can satisfy a formula as follows: L₂<L₃<L₁.

In the present embodiment, the first chip 2d can be a purple LED chip which emits light having a peak wavelength in a range of 390 nm to 430 nm. The phosphor in the first phosphor adhesive layer can be one or more selected from a green phosphor and a yellow phosphor, and the peak wavelength L₁ of emitting light of the phosphor in the first phosphor adhesive layer can be in a range of 530 nm to 590 nm. The phosphor in the second phosphor adhesive layer can be one or more selected from an indigo phosphor, a cyan phosphor and a blue phosphor, and the peak wavelength L₂ of the phosphor in the second phosphor adhesive layer can be in a range of 470 nm to 510 nm. In some embodiments, the phosphor in the second phosphor adhesive layer can be a blue phosphor. The phosphor in the third phosphor adhesive layer can be a green phosphor, and the peak wavelength L₃ of the phosphor in the third phosphor adhesive layer can be in a range of 510 nm to 540 nm. Glues in the phosphor adhesive layers can be selected from epoxy resin, silica gel and polyimide. FIG. 14 is a structural schematic diagram of an excitation mode of the packaging body in the present embodiment.

It should be understood by one skilled in the art that a number of the first chips 2d, a number of the chips 3d and a number of the third chips 7d can be not limited to one, and a ratio of the number of the first chips 2d to the number of the chips 3d and a ratio of the number of the chips 3d to the number of the third chips 7d can be not limited. In some embodiments, the number of the first chips 2d, the number of the third chips 7d and the number of the second chips 3d can be adjusted according to requirements of an actual luminescence spectrum.

Furthermore, in some embodiments, referring to FIG. 13, compared with the embodiment shown in FIG. 12, at least one fourth chip 9g can be disposed at the surface disposing the first chip 2g of the supporting member 1g, a peak wavelength of the fourth chip 9g can be identified as λD, which can be in a range of 420 nm to 465 nm, and the packaging layer 9g can further cover the fourth chip 9g. A peak wavelength of emitting light of the at least one first chip is identified as λA, which is in a range of 390 nm to 445 nm. A peak wavelength of emitting light of the at least one third chip is identified as λC, which is in a range of 420 nm to 465 nm. A peak wavelength of emitting light of the at least one second chip is identified as λB, which is in a range of 445 nm to 550 nm. The peak wavelength λA of emitting light of the at least one first chip 2g, the peak wavelength λC of emitting light of the at least one third chip 7g and the peak wavelength λB of emitting light of the at least one second chip 3g can satisfy formulas as follow: 0≤λB−λC≤130 nm, and 15≤λC−λA≤130 nm. In some embodiments, the first chip 2g can be a purple LED chip which emits light having a peak wavelength in a range of 390 nm to 430 nm.

In some embodiments, the packaging bodies were packaged in a structure as shown in FIG. 13, and tested. The samples of the embodiment were packaged by two-color COB method. A long wavelength phosphor adhesive layer 4g was merely disposed on a top surface of the second chip 3g, and a third phosphor adhesive layer 8g, that did not contain a red phosphor, was merely disposed on the top surface of the third chip 7g; and a second phosphor adhesive layer 6g, that did not contain a red phosphor, was merely disposed on a top surface of the first chip 2g. Three samples of the packaging body of the present disclosure were described in detail hereinafter.

In a sample of the packaging body denoted as HDK-S3-1, a fourth chip 9g was an LED chip which emitted a light having a peak wavelength of 455 nm; a first chip 2g was a purple LED chip which emitted a light having a peak wavelength of 430 nm; a third chip 7g was an LED chip which emitted a light having a peak wavelength of 455 nm; a second chip 3g was an LED chip which emitted a light having a peak wavelength of 465 nm; a phosphor in the long-wavelength phosphor adhesive layer 4g was a red phosphor; a phosphor of the second phosphor adhesive layer 6g that did not contain a red phosphor was a blue phosphor having a peak wavelength of emitting light of 475 nm; a phosphor of the third phosphor adhesive layer 8g was a green phosphor having a peak wavelength of emitting light of 515 nm; and a phosphor of the first phosphor adhesive layer, that did not contain a red phosphor, in the packaging layer 5g had a peak wavelength of emitting light of 530 nm.

In a sample of the packaging body denoted as HDK-S3-2, a fourth chip 9g was an LED chip which emitted a light having a peak wavelength of 455 nm; a first chip 2g was a purple LED chip which emitted a light having a peak wavelength of 430 nm; a third chip 7g was an LED chip which emitted a light having a peak wavelength of 445 nm; a second chip 3g was an LED chip which emitted a light having a peak wavelength of 445 nm; a phosphor in the long-wavelength phosphor adhesive layer 4g was a red phosphor; a phosphor of the second phosphor adhesive layer 6g that did not contain a red phosphor was a blue phosphor having a peak wavelength of emitting light of 475 nm; a phosphor of the third phosphor adhesive layer 8g was a green phosphor having a peak wavelength of emitting light of 515 nm; and a phosphor of the first phosphor adhesive layer that did not contain a red phosphor in the packaging layer 5g had a peak wavelength of emitting light of 530 nm.

In a sample of the packaging body denoted as HDK-S3-3, a fourth chip 9g was an LED chip which emitted a light having a peak wavelength of 455 nm; a first chip 2g was a purple LED chip which emitted a light having a peak wavelength of 420 nm; a third chip 7g was an LED chip which emitted a light having a peak wavelength of 420 nm; a second chip 3g was an LED chip which emitted a light having a peak wavelength of 420 nm; a phosphor in the long-wavelength phosphor adhesive layer 4g was a red phosphor; a phosphor of the second phosphor adhesive layer 6g that did not contain a red phosphor was a blue phosphor having a peak wavelength of emitting light of 475 nm; a phosphor of the third phosphor adhesive layer 8g was a green phosphor having a peak wavelength of emitting light of 515 nm; and a phosphor of the first phosphor adhesive layer, that did not contain a red phosphor, in the packaging layer 5g had a peak wavelength of emitting light of 530 nm.

FIG. 14 is a structural schematic diagram of an excitation mode of the packaging bodies in the samples above. The three samples were tested, and average values of the tests were shown in Table 4 hereinafter.

TABLE 4
test results of three samples of the present disclosure

| | | | Inner diameter | | Correlated | Forward | Forward | | | |
|---|---|---|---|---|---|---|---|---|---|---|
| | | | of emitting | Color | color | current | current | | Luminous | Maximum |
| | Size of the | Connection | surface | rendering | temperature | I_{Fmax} | I_{F} | Power | Efficiency | Power |
| Sample | Substrate | scheme | (mm) | index Ra | CCT(K) | (mA) | (mA) | (W) | (lm/W) | P(W) |
| HDK-S3-1-C | 15.8 × 15.8 | 12C2B | 9 | 80 | 6500 | 600 | 330 | 12 | 135 | 21 |
| high color | | | | | | | | | | |
| temperature | | | | | | | | | | |
| HDK-S3-1-W | 15.8 × 15.8 | 12C2B | 9 | 80 | 2700 | 600 | 330 | 12 | 120 | 21 |
| low color | | | | | | | | | | |
| temperature | | | | | | | | | | |
| HDK-S3-2-C | 15.8 × 15.8 | 12C2B | 9 | 90 | 6500 | 600 | 330 | 12 | 125 | 21 |
| high color | | | | | | | | | | |
| temperature | | | | | | | | | | |
| HDK-S3-2-W | 15.8 × 15.8 | 12C2B | 9 | 90 | 2700 | 600 | 330 | 12 | 110 | 21 |
| low color | | | | | | | | | | |
| temperature | | | | | | | | | | |
| HDK-S3-3-C | 15.8 × 15.8 | 12C2B | 9 | 90 | 6500 | 600 | 330 | 12 | 120 | 21 |
| high color | | | | | | | | | | |
| temperature | | | | | | | | | | |
| HDK-S3-3-W | 15.8 × 15.8 | 12C2B | 9 | 95 | 2700 | 600 | 330 | 12 | 100 | 21 |
| low color | | | | | | | | | | |
| temperature | | | | | | | | | | |

Comment: C represents series connection and B represents parallel connection in Table 4.

In the present embodiment, the first chip 2g can be a purple LED chip which emits light having a peak wavelength in a range of 390 nm to 430 nm, and the emitting light of the first chip 2g can excite the blue phosphor in the second phosphor adhesive layer 6g. The blue phosphor in the second phosphor adhesive layer can cover the top surface of the first chip 2g and sidewalls of the first chip 2g. Since the blue phosphor can only be excited by a purple light having a stronger energy than the blue light, the method for packaging the packaging body in the present embodiment can greatly improve excitation efficiency of the purple LED chip. At the same time, on the basis that the peak wavelength λA of emitting light of the at least one first chip 2g, the peak wavelength λC of emitting light of the at least one third chip 7g and the peak wavelength λB of emitting light of the at least one second chip 3g can satisfy the formulas as follow: 0≤λB−λC≤130 nm, and 15≤λC−λA≤130 nm, the luminous efficiency of the packaging body can be further improved.

Furthermore, a number of the fourth chips 9g, a number of the first chips 2d, a number of the chips 3g and a number of the third chips 7g can be not limited to one, and a ratio of the number of the fourth chips 9g, the number of the first chips 2g, the number of the chips 3g and the number of the third chips 7g can be not limited. In some embodiments, the number of the first chips 2g, the number of the third chips 7g and the number of the second chips 3g can be adjusted according to requirements of an actual luminescence spectrum.

The packaging bodies in the embodiments above can effectively solve technical problems of conventional white LED.

Firstly, in the present disclosure, chips having different emission wavelengths can be used, therefore phosphors having different excitation wavelengths can be excited. When a peak wavelength of an exciting light is in arrange of 360 nm to 400 nm, a relative excitation efficiency of a phosphor having a peak wavelength of emitting light of 495 nm can be greater than 80%. When a peak wavelength of an exciting light is in arrange of 420 nm to 470 nm, relative excitation efficiencies of a phosphor having a peak wavelength of emitting light of 518 nm, a phosphor having a peak wavelength of emitting light of 530 nm and a phosphor having a peak wavelength of emitting light of 535 nm can be greater than 80%. When an emitting light is a short-wavelength blue light, relative excitation efficiencies of a phosphor having a peak wavelength of emitting light of 655 nm and a phosphor having a peak wavelength of emitting light of 660 nm can be relatively large. However, a large amount of energy will be transformed to heat by lattice vibration due to relatively large Stokes shift. For example, when a blue light having a wavelength of 470 nm (photon energy of which is 2.61 eV) is used to excite a red light having a wavelength of 655 nm (photon energy of which is 1.89 eV), the relative excitation efficiency is 60%, and the photon energy loss is 0.72 eV. When a blue light having a wavelength of 440 nm (photon energy of which is 2.81 eV) is used to excite a red light having a wavelength of 655 nm (photon energy of which is 1.89 eV), the relative excitation efficiency is 70%, and the photon energy loss is 0.92 eV. That is, when an excitation light having a shorter excitation wavelength is used to excite a phosphor, the excitation efficiency can be improved by 10%, but the photon energy loss increased by 28%. Moreover, considering gently change of red excitation spectrum in a range of 450 nm to 500 nm, a relative excitation efficiency can slowly decrease to 55% from 65%. Therefore, it is suitable to excite a red phosphor with a light having a peak wavelength in a range of 450 nm to 500 nm. Excitation lights that are not absorbed can supplement deficient blue light and green light in the spectrum and excite an external yellow phosphor or an external cyan phosphor to improve the color rendering index.

Secondly, a packaging body containing chips having different peak wavelengths can effectively prevent the blue light and the green light from being absorbed again by red phosphor, and only little amount of the green light and the blue light can illuminate on the red phosphor. This can facilitate improving the amount of the green light and the blue light in the spectrum to increase the color rendering index.

Thirdly, according to Stokes shift, for one phosphor, a wavelength of an emitting light will shift along with shift of a wavelength of an excitation light. Therefore, in the present disclosure, a red fluorescence having a relatively long wavelength can be obtained by exciting a red phosphor with a long-wavelength fluorescence emitted by a long-wavelength chip. Similarly, a cyan fluorescence having a relatively short wavelength can be obtained by exciting a cyan phosphor with a short-wavelength fluorescence emitted by a short-wavelength chip. Therefore, a fluorescence band spectrum of a packaging body can be broader, and the color rendering index can be further improved. When the phosphor is excited by a light having a relatively short wavelength, the luminescence spectrum will shift towards short wavelength. Similarly, when the phosphor is excited by a light having a relatively long wavelength, the luminescence spectrum will shift towards long wavelength. Therefore, in the present disclosure, light emitted from a long-wavelength chip can be used to excite the red phosphor, achieving a bathochromic shift and obtaining a greater color rendering index. The cyan light can also have the same advantage.

Fourthly, a color temperature of the packaging body can be adjusted by changing a ratio of the number of the red chips to the number of the blue chips. In a conventional art, the color temperature of a light source can be changed by adjusting an amount of a red phosphor or other phosphors in the entire phosphor layer, but this may result in an emitting surface packaged by COB method being dark and turbid. However, in the present disclosure, the chips containing pure red phosphor are packaged by CSP method, and the color temperature can be changed by changing the number of the chips containing pure red phosphor. For example, 94 of chips having a size of 14 mil×30 mil can be disposed on an emitting surface having a diameter of 12.3 mm. When the preset color temperature is 4000K, the 94 of chips can include 48 of red chips and 46 of blue chips. When the preset color temperature is 3000 K, the 94 of chips can include 61 of red chips and 33 of blue chips. That is, the color temperature can be changed by adjusting the ratio of the number of the red chips to the number of the blue chips, other than accurately weighting the phosphor with a high precision balance and changing the amount of the red phosphor in the entire packaging layer in the conventional art. A light source prepared by a method in the present disclosure can have a different appearance, compared with that in the conventional art. Light source of the present disclosure with high-color rendering index and high luminous efficiency can be clearer, and the blue chip and the red chip in a CSP chip can be seen clearly. And the color temperature of the light source can be changed by adjusting the ratio of the number of the red chips to the number of the blue chips.

In some embodiments, referring to FIG. 2, a peak wavelength of emitting light of the first chip 2 can be identified as λA, and in a range of 420 nm to 465 nm. A peak wavelength of emitting light of the second chip 3 can be identified as λB, which can be in a range of 445 nm to 550 nm. The peak wavelength λA of emitting light of the first chip 2 and the peak wavelength λB of emitting light of the second chip 3 can satisfy a formula as follow: 0≤λB−λA≤130 nm. At this time, the first chip 2 can be a first blue chip, and the second chip 3 can be a second blue chip. The long-wavelength phosphor adhesive layer 4 can be consisted of a glue and the long-wavelength phosphor having a emission wavelength in a range of 600 nm to 1000 nm. A weight ratio of the long-wavelength phosphor to the glue is in a range of 0.2:1 to 5:1. In some embodiments, the first phosphor adhesive layer in the packaging layer 5 can include at least one of a green phosphor having an emission wavelength in a range of 500 nm to 550 nm and a yellow phosphor having an emission wavelength in a range of 550 nm to 600 nm, and does not include a blue phosphor having an emission wave length in a range of 450 nm to 500 nm or a long-wavelength phosphor having an emission wavelength in a range of 600 nm to 1000 nm.

When color temperature of the packaging body in entire is required as greater than 4500 K, the number of the plurality of first chips 2 can account for 5% to 30% in a sum of the number of the plurality of first chips 2 and the number of the plurality of second chips 3. When the color temperature of the entire packaging body is equal to or less than 4500 K, the number of the second chips 3 can account for 30% to 80% in a total number of the plurality of first chips 2 and the plurality of the second chips 3.

In some embodiments, the long-wavelength phosphor adhesive layer 4 can be disposed on the top surface and sidewalls of the second chip 3, forming a CSP packaging structure. Alternatively, the long-wavelength phosphor adhesive layer 4 can be disposed on the top surface of the second chip 3, forming a WLP packaging structure. A thickness of the long-wavelength phosphor adhesive layer 4 on the top surface of the second chip 3 can be in a range of 20 μm to 400 μm, and a thickness of the long-wavelength phosphor adhesive layer 4 on the sidewalls of the second chip can be in a range of 0 to 400 μm (e.g., in a range of 20 μm to 400 μm).

In some embodiments, the long-wavelength phosphor having the emission wavelength in a range of 600 nm to 1000 nm can include one or two of a red phosphor and a near infrared phosphor.

Light sources of the present disclosure can be used for illuminating a meat product. When the light source is used for illuminating beef, the long-wavelength phosphor can include a red phosphor having an emission wavelength in a range of 658 nm to 660 nm, and a weight of the red phosphor having an emission wavelength in a range of 658 nm to 660 nm accounts for 50% or above of a weight of the long-wavelength phosphor. When the light source is used for illuminating pork, the long-wavelength phosphor includes a red phosphor having an emission wavelength in a range of 605 nm to 630 nm and does not comprises a phosphor having an emission wavelength greater than 630 nm.

In the packaging bodies above, chips having different emission wavelengths are used, therefore phosphors having different excitation wavelengths can be excited. That is, a short-wavelength fluorescence emitted from a short-wavelength chip can excite a short-wavelength phosphor, and a long-wavelength fluorescence emitted from a long-wavelength chip can excite a long-wavelength phosphor. Meanwhile, a short-wavelength fluorescence emitted by the short-wavelength phosphor will not excite the long-wavelength phosphor and be consumed again. Therefore, optimal quantum yield can be achieved and luminous efficiency of a light source can be improved via choosing an optimal excitation wavelength.

In the present disclosure, chips having different emission wavelengths are packaged in one packaging body. Compared with the conventional art, the long-wavelength phosphor can be packaged in local areas such as a top surface and sidewalls of a chip by CSP method or WLP method, and only a small amount of short-wavelength fluorescence and medium-wavelength fluorescence can illuminate on the long-wavelength phosphor. This can effectively prevent blue fluorescence and green fluorescence from being absorbed again by the long-wavelength phosphor, so as to improve both the luminous efficiency and color rendering index.

At the same time, according to Stokes shift, for one phosphor, a wavelength of an emitting light will shift along with shift of a wavelength of an excitation light. Therefore, in the present disclosure, a red fluorescence having a relatively long wavelength can be obtained by exciting a long-wavelength phosphor with a long-wavelength fluorescence emitted by a long-wavelength chip. Similarly, a blue fluorescence having a relatively short wavelength can be obtained by exciting a blue phosphor with a short-wavelength fluorescence emitted by a short-wavelength chip, and a green fluorescence having a relatively short wavelength can be obtained by exciting a green phosphor with a short-wavelength fluorescence emitted by a short-wavelength chip. Therefore, a fluorescence band spectrum of the packaging body can be broader, and the color rendering index can be further improved.

Furthermore, in the present disclosure, a color temperature of the packaging body can be adjusted by changing the ratio of the number of the red chips and the number of the blue chips. In conventional art, the color temperature of a light source is changed by adjusting an amount of a red phosphor or other phosphors in the entire phosphor layer, but this may result in an emitting surface packaged by COB method being dark and turbid. Besides, the phosphor is required to be accurately weighted with a high precision balance to change the color temperature. However, in the present disclosure, the chips are packaged by CSP method, respectively. Therefore, the color temperature can be changed by adjusting the ratio of the number of the red chips to the number of the blue chips.

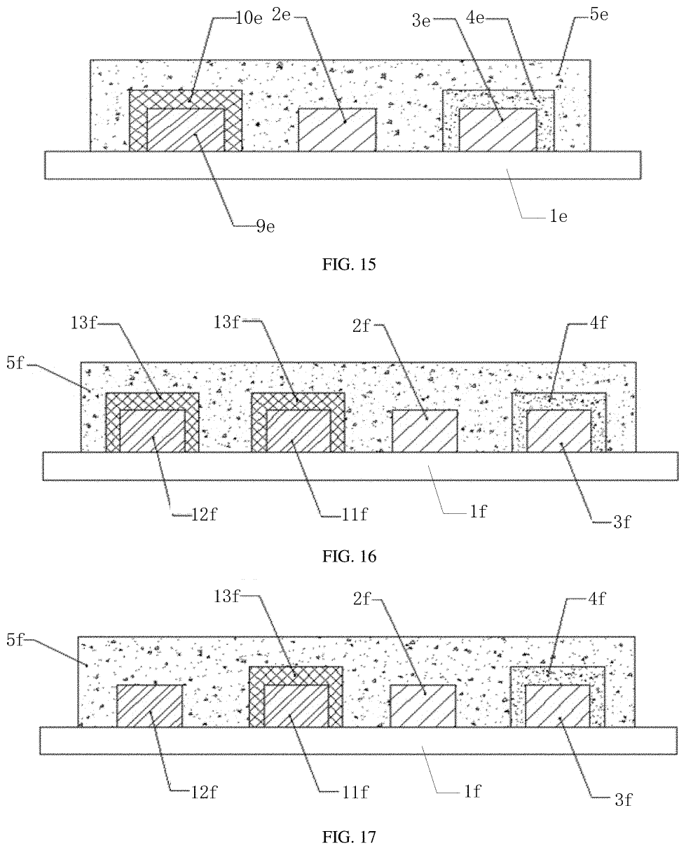

Furthermore, referring to FIG. 15, the present embodiment provides another embodiment of a packaging body. In the packaging body, the support member 1e includes a first chip 2e and a second chip 3e. At least one third chip 9e is disposed on the surface locating the first chip 2e of the support member 1e. The third chip 9e can be a purple chip or a near ultraviolet chip, and a long-wavelength phosphor adhesive layer 4e can be disposed at least a top surface of the second chip 2e, and a short-wavelength phosphor adhesive layer 10e can be disposed on the surface of the third chip 9e.

Wherein, a first chip 2e can be a first blue chip, and a peak wavelength of emitting light of the first chip is identified as λA, which is in a range of 420 nm to 465 nm; a peak wavelength of emitting light of the second chip 3e can be identified as λB, which is in a range of 445 nm to 550 nm; and a peak wavelength of emitting light of the third chip 9e is identified as λC, which is in a range of 370 nm to 420 nm. The peak wavelength λA of emitting light of the first chip 2e and the peak wavelength λB of emitting light of the at least one second chip 3e can satisfy a formula as follow: 0≤λB−λA≤130 nm.

The long-wavelength phosphor adhesive layer is consisted of a glue and the long-wavelength phosphor having a emission wavelength in a range of 600 nm to 1000 nm; a mass ratio of the long-wavelength phosphor to a glue is in a range of 0.2:1 to 5:1. The short-wavelength phosphor adhesive layer can include a glue and a short-wavelength phosphor having a emission wavelength in a range of 450 nm to 500 nm. Wherein, a mass ratio of the short-wavelength phosphor in the first short-wavelength phosphor adhesive layer to a glue is in a range of 0.2:1 to 5:1. In some embodiments, a ratio of a number of the third chips 9e to a number of the first chips 2e is in a range of 1:1 to 1:5.

Wherein, the short-wavelength phosphor adhesive layer 10e can be disposed on the top surface and sidewalls of the purple chip or near-ultraviolet chip (i.e., the third chip 9e), forming a CSP packaging structure. Alternatively, the short-wavelength phosphor adhesive layer can be disposed the top surface of the purple chip or the near-ultraviolet chip (i.e., the third chip 9e), forming a WLP packaging structure. In some embodiments, a thickness of the short-wavelength phosphor adhesive layer on the top surface of the purple chip or near-ultraviolet chip (i.e., the third chip 9e) can be in a range of 20 μm to 400 μm, and a thickness of the short-wavelength phosphor adhesive layer on the sidewalls of the purple chip or near-ultraviolet chip (i.e., the third chip 9e) can be in a range of 0 to 400 μm.

When the light source is used for illuminating seafood, the weight ratio of the short-wavelength phosphor in the short-wavelength phosphor adhesive layer 10e to a glue can be in a range of 2:1 to 5:1; and the ratio of the number of the third chips 9e to the number of the first chips 2e can be in a range of 1:1 to 1:3.

Wherein, the long-wavelength phosphor adhesive layer 4e can be disposed on the top surface and sidewalls of the second chip 3e, forming a CSP packaging structure. Alternatively, the long-wavelength phosphor adhesive layer 4e can be disposed the top surface of the second chip 3e, forming a WLP packaging structure. In some embodiments, a thickness of the long-wavelength phosphor adhesive layer 4e on the top surface of the second chip 3e can be in a range of 20 μm to 400 μm, and a thickness of the long-wavelength phosphor adhesive layer 4e on the sidewalls of the second chip can be in a range of 0 to 400 μm. The long-wavelength phosphor having the emission wavelength in a range of 600 nm to 1000 nm in the packaging layer 5e can include one or two of a red phosphor and a near infrared phosphor.

The packaging bodies having the above structures have following advantages. In the above spectrum dimming packaging bodies, chips having different emission wavelengths can be used, therefore phosphors having different excitation wavelengths can be excited. That is, a short-wavelength fluorescence emitted from a short-wavelength chip can excite a short-wavelength phosphor, and a long-wavelength fluorescence emitted from a long-wavelength chip can excite a long-wavelength phosphor. Meanwhile, a short-wavelength fluorescence emitted by the short-wavelength phosphor will not excite the long-wavelength phosphor and be consumed again. Therefore, optimal quantum yield can be achieved and luminous efficiency of a light source can be improved via choosing an optimal excitation wavelength.

Chips having different emission wavelengths are packaged by different methods, respectively. Compared with the conventional art, the long-wavelength phosphor can be packaged in local areas such as a top surface and sidewalls of a chip by CSP method or WLP method, and only a small amount of short-wavelength fluorescence and medium-wavelength fluorescence can illuminate on the long-wavelength phosphor. This can effectively prevent cyan fluorescence, blue fluorescence and green fluorescence from being absorbed again by the long-wavelength phosphor. For cyan light having low excitation efficiency, the method in the present disclosure can effectively reduce secondary loss of cyan fluorescence and improve the luminous efficiency and color rendering index.

In addition, according to Stokes shift, for one phosphor, a wavelength of an emitting light will shift along with shift of a wavelength of an excitation light. Therefore, in the present disclosure, a red fluorescence having a relatively long wavelength can be obtained by exciting a long-wavelength phosphor with a long-wavelength fluorescence emitted by a long-wavelength chip. Similarly, a cyan fluorescence having a relatively short wavelength can be obtained by exciting a cyan phosphor with a short-wavelength fluorescence emitted by a short-wavelength chip; a blue fluorescence having a relatively short wavelength can be obtained by exciting a blue phosphor with a short-wavelength fluorescence emitted by a short-wavelength chip; and a green fluorescence having a relatively short wavelength can be obtained by exciting a green phosphor with a short-wavelength fluorescence emitted by a short-wavelength chip. Therefore, a fluorescence band spectrum of a packaging body can be broader, and the color rendering index can be further improved.

Furthermore, in the present disclosure, a color temperature of the packaging body can be adjusted by changing a ratio of a number of a red chip and a number of a blue chip. In conventional art, the color temperature of a light source is changed by adjusting an amount of a red phosphor or other phosphors in the entire phosphor layer, but this may result in an emitting surface packaged by COB method being dark and turbid. Besides, in the conventional art, the phosphor needs to be accurately weighted with a high precision balance to change the color temperature. However, in the present disclosure, the chips are packaged by CSP method, respectively. Therefore, the color temperature can be changed by adjusting the ratio of the number of the red chips to the number of the blue chips.

In some embodiments, referring to FIG. 16, a support member if can include a first chip 2f, a second chip 3f, at least one third chip 11f and at least one fourth chip 12f. The third chip 11f and the fourth chip 12f can be disposed on the surface of the support member 11f on which the first chip 2f is disposed. Wherein, the first chip 2f can be a first blue chip, a peak wavelength of emitting light of the first chip 2f is identified as λA, which is in a range of 420 nm to 465 nm. The second chip 3f can be a second blue chip, and a peak wavelength of emitting light of the second chip 3f is identified as λB, which is in a range of 445 nm to 550 nm. A long-wavelength phosphor adhesive layer 4f can be disposed on a surface of the second chip 3f, and the long-wavelength phosphor adhesive layer 4f consisted of a glue and along-wavelength phosphor, and a weight ratio of the long-wavelength phosphor to the glue is in a range of 0.2:1 to 5:1. The third chip 11f can be a purple chip and a short-wavelength phosphor adhesive layer 13f can be disposed on the surface of the third chip 11f. A peak wavelength of emitting light of the third chip 11f can be identified as λC, which can be in a range of 400 nm to 420 nm. The fourth chip 12f can be a purple chip or a near ultraviolet chip, a peak wavelength of emitting light of the fourth chip can be identified as λD, which can be in a range of 370 nm to 400 nm. A short-wavelength phosphor adhesive layer can be disposed on the surface of the fourth chip (referring to FIG. 16); alternatively, the fourth chip can be provided without the short-wavelength phosphor adhesive layer (referring to FIG. 17).

In the present embodiment, the long-wavelength phosphor adhesive layer 4f can be consisted of a glue and a long-wavelength phosphor having an emission wavelength in a range of 600 nm to 980 nm, and a weight ratio of the long-wavelength phosphor to the glue can be in a range of 0.2:1 to 5:1. The short-wavelength phosphor adhesive layer 13f disposed on the third chip 11f and the fourth chip 13f can include a glue and a blue phosphor having an emission wavelength in a range of 450 nm to 500 nm. Wherein, a weight ratio of the blue phosphor in the short-wavelength phosphor adhesive layer 13f to the glue can be in a range of 0.2:1 to 5:1. In some embodiments, a number of the second chips 3f can account for 50% to 75% in a total number of the first chip 2f, the second chip 3f, the third chip 11f and the fourth chip 12f. In some embodiments, a ratio of the number of the third chips 11f to the number of the fourth chips 12f can be in a range of 1:1 to 1:3. In some embodiments, a ratio of a number of the first chip 2f to a sum of the number of the third chips 11f and the number of the fourth chips 12f can be in a range of 2:2 to 2:0.5.

In some embodiments, the short-wavelength phosphor adhesive layer can be disposed on the top surface and sidewalls of corresponding chip, forming a CSP packaging structure. Alternatively, the short-wavelength phosphor adhesive layer can be disposed the top surface of the corresponding chip, forming a WLP packaging structure. A thickness of the short-wavelength phosphor adhesive layer on the top surface of the corresponding chip can be in a range of 20 μm to 400 μm, and a thickness of the short-wavelength phosphor adhesive layer on the sidewalls of the corresponding chip can be in a range of 0 to 400 μm.

The long-wavelength phosphor adhesive layer 4f can be disposed on the top surface and sidewalls of the second chip 3f, forming a CSP packaging structure. Alternatively, the long-wavelength phosphor adhesive layer 4f can be disposed the top surface of the third chip 11f forming a WLP packaging structure. In some embodiments, a thickness of the long-wavelength phosphor adhesive layer 4f on the top surface of the second chip 3f can be in a range of 20 μm to 400 μm, and a thickness of the long-wavelength phosphor adhesive layer 4f on the sidewalls of the second chip 3f can be in a range of 0 to 400 μm. The long-wavelength phosphor having the emission wavelength in a range of 600 nm to 980 nm in the packaging layer 5f can include one or two of a red phosphor and a near infrared phosphor.

Compared with conventional method, the present embodiment has following advantages. Chips having different emission wavelengths can cooperate with phosphor adhesive layers, so that the spectrum can be broad. That is, a light source including the packaging body of the present embodiment can emit light having a long-wavelength band, which can be used for accelerating plant growing, photosynthesis and blossoming. And the light source can further emit light having a short-wavelength band which can be used for facilitating generating anti-oxidant chemical compositions of plants such as anthocyanin, lutein and the like, and facilitating the plant growing better. The light source containing the packaging body of the present embodiment can facilitate a certain plant to grow better, and a planter can define the light according to requirement of the plant. A quantum yield of the light in the present disclosure can be 3.75 μmol/J. A service life of the light in the present disclosure can be 36000 hours. A service life of a high pressure sodium lamp is only 8000 hours. Compared with light sources such as the high pressure sodium lamp and the like, the light of the present disclosure has high light yield and low heat production, and can provide ideal spectrum for facilitating growth of the plant.

Chips having different emission wavelengths are used, therefore phosphors having different excitation wavelengths can be excited. That is, a short-wavelength fluorescence emitted from a short-wavelength chip can excite a short-wavelength phosphor, and a long-wavelength fluorescence emitted from a long-wavelength chip can excite a long-wavelength phosphor. Meanwhile, a short-wavelength fluorescence emitted by the short-wavelength phosphor will not excite the long-wavelength phosphor and be consumed again. Therefore, optimal quantum yield can be achieved and luminous efficiency of a light source can be improved via choosing an optimal excitation wavelength. At the same time, a color temperature of the packaging body can be adjusted by changing a ratio of the number of the red chips to the number of the blue chips. In conventional art, the color temperature of a light source is changed by adjusting an amount of a red phosphor or other phosphors in the entire phosphor layer, but this may result in an emitting surface packaged by COB method being dark and turbid. Besides, in a conventional art, the phosphor needs to be accurately weighted with a high precision balance to change the color temperature. However, in the present disclosure, the chips are packaged by CSP method, respectively. Therefore, the color temperature can be changed by adjusting the ratio of the number of the red chips to the number of the blue chips.

The present disclosure further provides a method for preparing the packaging body, which will be described in detail hereinafter. The method can include following steps.

Step S1, providing at least one first chip and at least one second chip, wherein a long-wavelength phosphor adhesive layer is disposed on at least a top surface of the at least one second chip.

In some embodiments, the first chip can be a first blue chip, and the second chip can be a second blue chip. The long-wavelength phosphor adhesive layer can be disposed on the top surface of the second chip, forming a long-wavelength packaging body having a WLP packaging structure or a CSP packaging structure. The long-wavelength phosphor adhesive layer can be consisted of a glue and the long-wavelength phosphor having a emission wavelength in a range of 600 nm to 1000 nm. A mass ratio of the long-wavelength phosphor to the glue can be in a range of 0.2:1 to 5:1. One skilled in the art should understand that the mass ratio of the long-wavelength phosphor to the glue is a ratio of a mass of the long-wavelength phosphor to a mass of the glue. The wavelength of the phosphor is an emission wavelength of the phosphor.

In some embodiments, the first chip can be a first blue chip, and the second chip can be a second blue chip. The step S1 can further includes: providing a third chip, which can be a purple chip or a near-ultraviolet chip. A long-wavelength phosphor adhesive layer can be disposed on the top surface of the second chip, forming a long-wavelength packaging body having a WLP packaging structure or a CSP packaging structure. The long-wavelength phosphor adhesive layer can be consisted of a glue and the long-wavelength phosphor having a emission wavelength in a range of 600 nm to 1000 nm. A mass ratio of the glue to the long-wavelength phosphor can be in a range of 0.2:1 to 5:1. A short-wavelength phosphor adhesive layer can be dispose on a surface of the third chip, obtaining a short-wavelength packaging body in a form of a CSP packaging structure or a WLP packaging structure. Wherein, the short-wavelength phosphor adhesive layer can include a glue and a short-wavelength phosphor having an emission wavelength in a range of 450 nm to 500 nm. A weight ratio of the short-wavelength phosphor in the short-wavelength phosphor adhesive layer to the glue can be in a range of 0.2:1 to 5:1.

In some embodiments, the first chip can be a first blue chip, and the second chip can be a second blue chip. The step S1 can further include: providing a third chip and a fourth chip. The third chip can be a purple chip, and a blue phosphor chip can be disposed on the surface of the blue chip. The fourth chip can be a near ultraviolet chip with or without a sixth short-wavelength phosphor adhesive layer. The blue phosphor adhesive layer of the third chip and the fourth chip can include a glue and a blue phosphor having an emission wavelength in a range of 450 nm to 500 nm. A weight ratio of the blue phosphor in the blue phosphor adhesive layer to the glue can be in a range of 0.2:1 to 5:1.

Step S2, designing a ratio of a number of the second chip to a total number of the first chip and the second chip according to a preset color temperature of a packaging body product, defining a chromaticity coordinate of the second chip on a CIE chromaticity diagram according to the ratio of the number of the second chip to the total number of chips as a red point (X1, Y1), and defining a chromaticity coordinate of the first chip on the CIE chromaticity diagram according to the ratio of the number of the first chip to the total number of the chips as a blue point (X2, Y2).

In some embodiments, when a first chip and a second chip are provided in step S1, the step S2 can include the following steps. When color temperature of the packaging body in entire is required as greater than 4500 K, a number of the second chips can account for 5% to 30% in a sum of the number of the chips; when the color temperature of the entire packaging body is equal to or less than 4500 K, a number of the second chip can account for 30% to 80% in a total number of the chips. Defining a chromaticity coordinate of the second chip on a CIE chromaticity diagram according to the ratio of the number of the second chip to the total number of the first chip and the second chip as a red point (X1, Y1), and defining a chromaticity coordinate of the first chip on the CIE chromaticity diagram according to the ratio of the number of the first chip to the total number of the first chip and the second chip as a blue point (X2, Y2).

In some embodiment, when a first chip, a second chip and a third chip are provided in step S1, the step S2 can include the following steps. Designing a ratio of a number of the second chip to a total number of the chips according to a preset color temperature of a packaging body product. When color temperature of the packaging body in entire is required as greater than 4500 K, a number of the second chips can account for 5% to 30% in a sum of the number of the chips; when the color temperature of the entire packaging body is equal to or less than 4500 K, a number of the second chip can account for 30% to 80% in a total number of the chips. Defining a chromaticity coordinate of the second chip on a CIE chromaticity diagram according to the ratio of the number of the second chip to the total number of the first chip and the second chip as a red point (X1, Y1). Defining a ratio of a number of the third chip to a number of the first chip in a range of 1:1 to 1:5 according to relative height at peak wavelength λA of emitting light of the first chip and relative height at 480 nm in the spectrum. Defining a chromaticity coordinate of the third chip and the first chip on the CIE chromaticity diagram according to the ratio of the number of the first chip to the third chip as a mixed blue point (X2, Y2).

In some embodiment, when a first chip, a second chip, a third chip and a fourth chip are provided in step S1, the step S2 can include the following steps: designing a ratio of a number of the second chip to a total number of the chips according to requirement of a packaging body product for illuminating a plant, a number of the second chip accounts for 50% to 75% in a total number of the first chip, the second chip, the third chip and the fourth chip; defining a chromaticity coordinate of the second chip on a CIE chromaticity diagram according to the ratio of the number of the second chip to the total number of the first chip and the second chip as a red point (X1, Y1); presetting a ratio of a number of the third chip to a number of the fourth chip as in a range of 1:1 to 1:3. Setting the number of the first chip, and ensuring that a ratio of the number of the first chip to a total number of the third chip and the fourth chip is in a range of 2:0.5 to 2:2; and defining a chromaticity coordinate of the first chip on the CIE chromaticity diagram according to the ratio of the number of the first chip to the total number of the first chip and the second chip as a blue point (X2, Y2).

Step S3 of pre-controlling the color temperature can include the following steps:

fixing the first chip and the second chip to corresponding positions on a support member, respectively;

making the first chip and the second chip emit light, and looking up a chromaticity coordinate of the lighted first chip and the lighted least one second chip on the CIE chromaticity diagram, wherein the chromaticity coordinate of the lighted first chip and lighted least one second chip is identified as a mixed point (X3, Y3);

ensuring that the Y3 in mixed point (X3, Y3) is greater than or equal to 0.08 and less than or equal to 0.30, and the X3 in mixed point (X3, Y3) is greater than or equal to 0.22 and less than or equal to 0.43, thereby pre-controlling a range of the color temperature; and if the Y3 in mixed point (X3, Y3) is not greater than or equal to 0.08 and less than or equal to 0.30, and the X3 in mixed point (X3, Y3) is not greater than or equal to 0.22 and less than or equal to 0.43, repeating step S2.

In some embodiments, when a first chip and a second chip are provided in the step S1, the step S3 can further include following step: ensuring that the Y3 is greater than or equal to 0.08 and less than or equal to 0.20, and the X3 is greater than or equal to 0.22 and less than or equal to 0.43.

In some embodiments, when a first chip, a second chip and a third chip are provided in the step S1, the step S3 can further include following step: ensuring that the Y3 is greater than or equal to 0.09 and less than or equal to 0.20, and the X3 is greater than or equal to 0.22 and less than or equal to 0.37.

In some embodiments, when a first chip, a second chip, a third chip and a fourth chip are provided in the step S1, the step S3 can further include following step: ensuring that the Y3 is greater than or equal to 0.16 and less than or equal to 0.30, and the X3 is greater than or equal to 0.28 and less than or equal to 0.42.

Step S4, looking up a chromatic coordinate of the preset color temperature of the packaging body product along the Planckian locus on the CIE chromaticity diagram according to requirements of the present color temperature of the packaging body product, and identifying the chromaticity coordinate of the preset color temperature of the packaging body product as a white point (X4, Y4); obtaining a specific chromatic coordinate or a range of chromatic coordinates of a green point (X5, Y5) according to chromatic coordinates of the red point (X1, Y1), the blue point (X2, Y2), the mixed point (X3, Y3) and the white point (X4, Y4); selecting a suitable first phosphor according to the chromatic coordinate of the green point, and mixing the first phosphor with a glue to form a first phosphor adhesive layer; entirely packaging the at least one first chip and the at least one second chip on the supporting member with the first phosphor adhesive layer to form a packaging layer; and heating and solidifying to obtain the packaging body product.

In some embodiment, in the step S4, selecting the suitable first phosphor can include: selecting a green phosphor having an emission wavelength in a range of 500 nm to 550 nm and a yellow phosphor having an emission wavelength in a range of 550 nm to 600 nm with a suitable weight ratio as the suitable first phosphor.

Step S5, detecting a luminescence spectrum and the color temperature of the packaging body product, if a chromatic coordinate of the packaging body product is different from that along the Planckian locus, adjusting constituents of the first phosphor in the packing layer; if the color temperature does not conform to the preset color temperature, adjusting the ratio of the number of the at least one second chip to the total number of the at least one first chip and the at least one second chip, and repeating the steps S3 to S5.

In some embodiments, if a vertical coordinate of the chromatic coordinate of the packaging body product is greater than that along the Planckian locus on the CIE chromaticity diagram, a green phosphor is added into the first phosphor, and if the vertical coordinate of the chromatic coordinate of the packaging body product is less than that along the Planckian locus on the CIE chromaticity diagram, a yellow phosphor is added into the first phosphor.

In some embodiments, the step S5 can further include following steps: if the luminescence spectrum does not meet preset requirements of the packaging body product, adjusting a number of the third chip and repeating the steps S3 to S5.

In some embodiments, when a first chip, a second chip, a third chip and a fourth chip are provided in the step S1, the step S5 can further include: if the luminescence spectrum does not meet preset requirements of the packaging body product, adjusting the number of the at least one first chip, a number of the third chip and a number of the fourth chip according to the corresponding wave band, and repeating the steps S3 to S5.

The method for preparing the packaging body in the present disclosure will be further illustrated in conjunction with some embodiments.

### Embodiment 1: Preparing a Spectrum Dimming Packaging Body Having a Color Temperature of 4000 K

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm. The long-wavelength phosphor adhesive layer included a long-wavelength phosphor and a glue, and the wavelength of emitting light of the long-wavelength phosphor was 620 nm. A mass ratio of the long-wavelength phosphor adhesive layer to the glue was 1.7:1. A thickness of the long-wavelength phosphor adhesive layer on the top surface of the second chip was 200 μm, and a thickness of the long-wavelength phosphor adhesive layer on the sidewalls of the second chip was 120 μm.

The spectrum dimming packaging body could include 40 to 50 chips. In the present embodiment, a number of the second chips was 22, a number of the first chips was 23. On the CIE chromaticity diagram, coordinate of the red point corresponding to the second chip was (0.5, 0.28), a coordinate of the blue point corresponding to the first chip was (0.0149, 0.0317), a coordinate of the mixed point was a coordinate of the blue point corresponding to the first chip was (0.2413, 0.0877), and a coordinate corresponding to the color temperature was (0.378, 0.377).

In the packaging layer of the present embodiment, a weight ratio of the glue was 70%, a weight ratio of the green phosphor was 27% and a weight ratio of the yellow phosphor was 3%.

### Embodiment 2: Preparing a Spectrum Dimming Packaging Body Having a Color Temperature of 3000 K, and the Packaging Body can be Used for Illuminating Meat Such as Beef

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm. The long-wavelength phosphor in the long-wavelength phosphor adhesive layer was a mixed phosphor, wherein a red phosphor having emission wavelength in a range of 658 nm to 660 nm accounted for more than 70% of the total amount of the mixed phosphor, and the other was a red phosphor having emission wavelength of 627 nm. A mass ratio of the phosphor in the long-wavelength phosphor adhesive layer to the glue was 3:1. A thickness of the long-wavelength phosphor adhesive layer on the top surface of the second chip was 200 μm, and a thickness of the long-wavelength phosphor adhesive layer on the sidewalls of the second chip was 120 μm.

The spectrum dimming packaging body could include about 50 chips. In the present embodiment, the number of the second chips was 28, the number of the first chips was 23. On the CIE chromaticity diagram, a coordinate of the red point corresponding to the second chip was (0.54, 0.28), a coordinate of the blue point corresponding to the first chip was (0.0149, 0.0317), a coordinate of the mixed point was (0.3224, 0.1433), and a coordinate corresponding to the color temperature was (0.418, 0.4115).

In the packaging layer of the present embodiment, a weight ratio of the glue was 65%, a weight ratio of the green phosphor was 19% and a weight ratio of the yellow phosphor was 16%.

### Embodiment 3: Preparing a Spectrum Dimming Packaging Body Having a Color Temperature of 6500 K, and the Packaging Body can be Used for Illuminating Seafood

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm. The phosphor in the long-wavelength adhesive layer was a red phosphor having a wavelength of emitting light of 620 nm. A mass ratio of the long-wavelength phosphor adhesive layer to the glue was 0.2:1. A thickness of the long-wavelength phosphor adhesive layer on the top surface of the second chip was 200 μm, and a thickness of the long-wavelength phosphor adhesive layer on the sidewalls of the second chip was 120 μm.

The spectrum dimming packaging body could include about 30 chips. In the present embodiment, a number of the second chip was 8, and a number of the first chip was 20. On the CIE chromaticity diagram, a coordinate of the red point corresponding to the second chip was (0.43, 0.21), a coordinate of the blue point corresponding to the first chip was (0.0149, 0.0317), a coordinate of the mixed point was (0.2205, 0.08017), and a coordinate corresponding to the color temperature was (0.3187, 0.3255).

In the packaging layer of the present embodiment, a weight ratio of the glue was 69%, a weight ratio of the green phosphor was 25% and a weight ratio of the yellow phosphor was 6%.

### Embodiment 4: Preparing a Spectrum Dimming Packaging Body Having a Color Temperature of 2500 K

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm. The phosphor in the long-wavelength adhesive layer was a red phosphor having a wavelength of emitting light of 650 nm. A mass ratio of the long-wavelength phosphor adhesive layer to the glue was 5:1. A thickness of the long-wavelength phosphor adhesive layer on the top surface of the second chip was 200 μm, and a thickness of the long-wavelength phosphor adhesive layer on the sidewalls of the second chip was 120 μm.

The spectrum dimming packaging body could include about 40 chips. In the present embodiment, the number of the second chips was 8, and the number of the first chips was 20. On the CIE chromaticity diagram, a coordinate of the red point corresponding to the second chip was (0.58, 0.305), a coordinate of the blue point corresponding to the first chip was (0.0149, 0.0317), a coordinate of the mixed point was (0.4101, 0.2073), and a coordinate corresponding to the color temperature was (0.483, 0.428).

In the packaging layer of the present embodiment, a weight ratio of the glue was 60%, a weight ratio of the green phosphor was 20% and a weight ratio of the yellow phosphor was 20%.

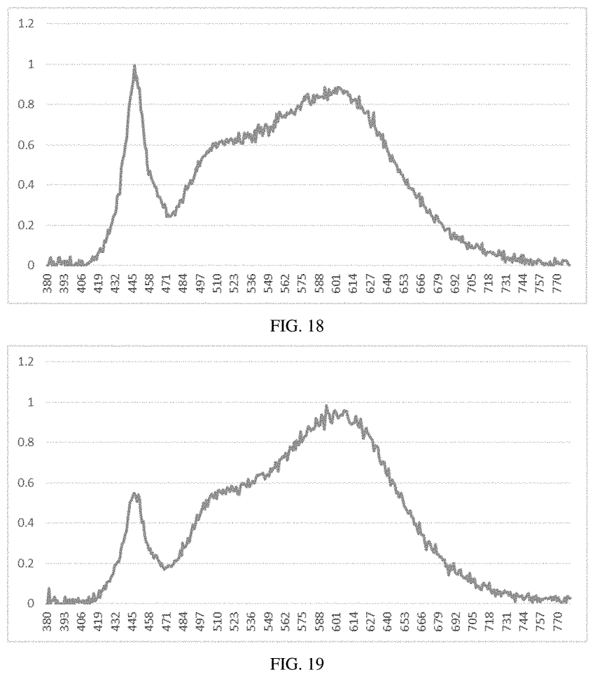

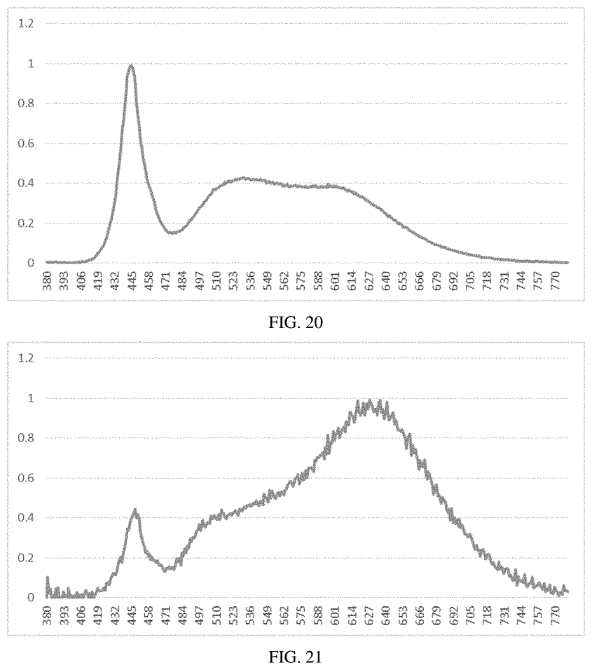

The spectrum dimming packaging bodies of embodiment 1 to embodiment 4 were packaged by COB method. And test results of packaging bodies of embodiment 1 to embodiment 4 and a conventional 1919 COB packaging body having a color temperature of 4000 K were shown in Table 5 herein after (the number of the packaging bodies were 10 in each sample). FIG. 18 to FIG. 21 were spectra of the spectrum dimming packaging bodies packaged by COB method in embodiment 1 to embodiment 4.

TABLE 5
test results of packaging bodies of embodiment 1 to embodiment 4 and a conventional packaging body

| | | | | | Conventional 1919 |
|---|---|---|---|---|---|
| | Embodiment 1 | Embodiment 2 | Embodiment 3 | Embodiment 4 | COB packaging |
| | (4000 K) | (3000 K) | (6500 K) | (2500 K) | (4000 K) |
| Interface of the | The emitting surface | The emitting surface | The emitting surface | The emitting surface | The color of the |
| packaging layer | is almost transparent, | is almost transparent, | is almost transparent, | is almost transparent, | emitting surface is |
| | and colors and | and colors and | and colors and | and colors and | dark and turbid. |
| | shapes of chips | shapes of chips | shapes of chips | shapes of chips | |
| | inside the packaging | inside the packaging | inside the packaging | inside the packaging | |
| | body can be seen | body can be seen | body can be seen | body can be seen | |
| | clearly. | clearly. | clearly. | clearly. | |
| Average Color | 98.3 | 97.9 | 97.5 | 98.5 | 96.1 |
| Rendering Index | | | | | |
| Average luminous | 119 | 107 | 115 | 90 | 92 |
| Efficiency (lm/W) | | | | | |
| Average mass of red | 68.5 | 73 | 52.8 | 79.4 | >150 |
| phosphor (mg) | | | | | |
| Average | 91.5 | 87.9 | 93.4 | 91.3 | About 95 |
| temperature of a 30 | | | | | |
| W substrate (degree | | | | | |
| centigrade) | | | | | |

It can be concluded from Table 5 and FIG. 18 to FIG. 21 that the chips in the packaging layer of the packaging body in the present disclosure can be seen clearly, preventing the short-wavelength fluorescence generated by exciting the short-wavelength phosphor from being absorbed again by the long-wavelength phosphor. Therefore, the luminous efficiencies of most of the light sources were improved by more than 11%, and the heat dissipation was good. The fluorescence band spectrum was broader and the color rending index improved a little. A color temperature of the packaging body was adjusted by changing a ratio of a number of the red chips to a number of the blue chips. This not only avoided weighing the phosphor with a high precision balance, but also largely decreasing the amount of the phosphor.

### Embodiment 5: Preparing a Spectrum Dimming Packaging Body Having a Color Temperature of 4000 K

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm.

The phosphor in the long-wavelength adhesive layer was phosphor having a wavelength of emitting light of 650 nm. A mass ratio of the long-wavelength phosphor adhesive layer to the glue was 1.7:1. A thickness of the long-wavelength phosphor adhesive layer on the top surface of the second chip was 200 μm, and a thickness of the long-wavelength phosphor adhesive layer on the sidewalls of the second chip was 0, i.e., the side walls were provided without the long-wavelength phosphor. The third chip was a purple chip or a near-ultraviolet chip having a size of 14 mil×30 mil, and a peak wavelength λC of emitting light of the third chip was 410 nm. The phosphor in the short-wavelength adhesive layer was phosphor having a wavelength of emitting light of 480 nm. A mass ratio of the short-wavelength phosphor adhesive layer to the glue was 2:1. A thickness of the short-wavelength phosphor adhesive layer on the top surface of the purple chip or the near-ultraviolet chip was 300 μm, and a thickness of the short-wavelength phosphor adhesive layer on the sidewalls of the purple chip or the near-ultraviolet chip was 120 μm.

The spectrum dimming packaging body could include 40 to 50 chips. According to a ratio of the chips, the number of the second chips was 18. On the CIE chromaticity diagram, a corresponding coordinate of the red point was (0.32, 0.14). A number of the third chips was 7, and a number of the first chips was 20. On CIE chromaticity diagram, and a corresponding coordinate of a combination of the first chips and the third chips was (0.162, 0.22). A coordinate of the mixed point was (0.28, 0.124), and a CIE chromaticity diagram coordinate of the color temperature was (0.384, 0.379). In the packaging layer of the present embodiment, a weight ratio of the glue was 70%, a weight ratio of the green phosphor was 28% and a weight ratio of the yellow phosphor was 2%.

### Embodiment 6: Preparing a Spectrum Dimming Packaging Body Having a Color Temperature of 3000 K

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm. The phosphor in the long-wavelength adhesive layer was phosphor having a wavelength of emitting light of 650 nm. A mass ratio of the long-wavelength phosphor adhesive layer to the glue was 4:1. A thickness of the long-wavelength phosphor adhesive layer on the top surface of the second chip was 200 μm, and a thickness of the long-wavelength phosphor adhesive layer on the sidewalls of the second chip was 120 μm.

The third chip was a purple chip or a near-ultraviolet chip having a size of 14 mil×30 mil, and a peak wavelength λC of emitting light of the third chip was 410 nm. The phosphor in the short-wavelength adhesive layer was phosphor having a wavelength of emitting light of 480 nm. A mass ratio of the short-wavelength phosphor adhesive layer to the glue was 2:1. A thickness of the short-wavelength phosphor adhesive layer on the top surface of the purple chip or the near-ultraviolet chip was 300 μm, and a thickness of the short-wavelength phosphor adhesive layer on the sidewalls of the purple chip or the near-ultraviolet chip was 120 μm.

The spectrum dimming packaging body could include 40 to 50 chips. According to a ratio of the chips, the number of the second chips was 22. On the CIE chromaticity diagram, a coordinate of the red point corresponding to the second chip was (0.384, 0.131). A number of the third chips was 5, and a number of the first chips was 18. On CIE chromaticity diagram, and a corresponding coordinate of a combination of the first chips and the third chips was (0.162, 0.21). A coordinate of the mixed point was (0.3121, 0.1453), and a CIE chromaticity diagram coordinate of the color temperature was (0.442, 0.402). In the packaging layer of the present embodiment, a weight ratio of the glue was 70%, a weight ratio of the green phosphor was 20% and a weight ratio of the yellow phosphor was 10%.

### Embodiment 7: Preparing a Spectrum Dimming Packaging Body Having a Color Temperature of 5000 K, which can be Used as a Chilled Light

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm. The phosphor in the long-wavelength adhesive layer was phosphor having a wavelength of emitting light of 650 nm. A mass ratio of the long-wavelength phosphor adhesive layer to the glue was 0.2:1. A thickness of the long-wavelength phosphor adhesive layer on the top surface of the second chip was 200 μm, and a thickness of the long-wavelength phosphor adhesive layer on the sidewalls of the second chip was 0 μm.

The third chip was a purple chip or a near-ultraviolet chip having a size of 14 mil×30 mil, and a peak wavelength λC of emitting light of the third chip was 410 nm. The phosphor in the short-wavelength adhesive layer was phosphor having a wavelength of emitting light of 480 nm. A mass ratio of the short-wavelength phosphor adhesive layer to the glue was 5:1. A thickness of the short-wavelength phosphor adhesive layer on the top surface of the purple chip or the near-ultraviolet chip was 400 μm, and a thickness of the short-wavelength phosphor adhesive layer on the sidewalls of the purple chip or the near-ultraviolet chip was 120 μm.

The spectrum dimming packaging body could include 30 to 40 chips. According to a ratio of the chips, the number of the second chips was 10. On the CIE chromaticity diagram, a coordinate of the red point corresponding to the second chip was (0.26, 0.1). A number of the third chips was 9, and a number of the first chips was 18. On CIE chromaticity diagram, and a corresponding coordinate of a combination of the first chips and the third chips was (0.163, 0.246). A coordinate of the mixed point was (0.24, 0.0965), and a CIE chromaticity diagram coordinate of the color temperature was (0.345, 0.359). In the packaging layer of the present embodiment, a weight ratio of the glue was 73%, a weight ratio of the green phosphor was 22% and a weight ratio of the yellow phosphor was 5%.

### Embodiment 8: Preparing a Spectrum Dimming Packaging Body Having a Color Temperature of 2800 K, which can be Used as a Chilled Light

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm. The phosphor in the long-wavelength adhesive layer was phosphor having a wavelength of emitting light of 650 nm. A mass ratio of the long-wavelength phosphor adhesive layer to the glue was 5:1. A thickness of the long-wavelength phosphor adhesive layer on the top surface of the second chip was 400 μm, and a thickness of the long-wavelength phosphor adhesive layer on the sidewalls of the second chip was 120 μm.

The third chip was a purple chip or a near-ultraviolet chip having a size of 14 mil×30 mil, and a peak wavelength λC of emitting light of the third chip was 410 nm. The phosphor in the short-wavelength adhesive layer was phosphor having a wavelength of emitting light of 480 nm. A mass ratio of the short-wavelength phosphor adhesive layer to the glue was 0.5:1. A thickness of the short-wavelength phosphor adhesive layer on the top surface of the purple chip or the near-ultraviolet chip was 100 μm, and a thickness of the short-wavelength phosphor adhesive layer on the sidewalls of the purple chip or the near-ultraviolet chip was 0 μm.

The spectrum dimming packaging body could include 40 to 50 chips. According to a ratio of the chips, the number of the second chips was 20. On the CIE chromaticity diagram, a coordinate of the red point corresponding to the second chip was (0.483, 0.24). A number of the third chips was 7, and a number of the first chips was 18. On CIE chromaticity diagram, and a corresponding coordinate of a combination of the first chips and the third chips was (0.161, 0.18). A coordinate of the mixed point was (0.3598, 0.1896), and a CIE chromaticity diagram coordinate of the color temperature was (0.483, 0.428).

In the packaging layer of the present embodiment, a weight ratio of the glue was 70%, a weight ratio of the green phosphor was 18% and a weight ratio of the yellow phosphor was 12%.

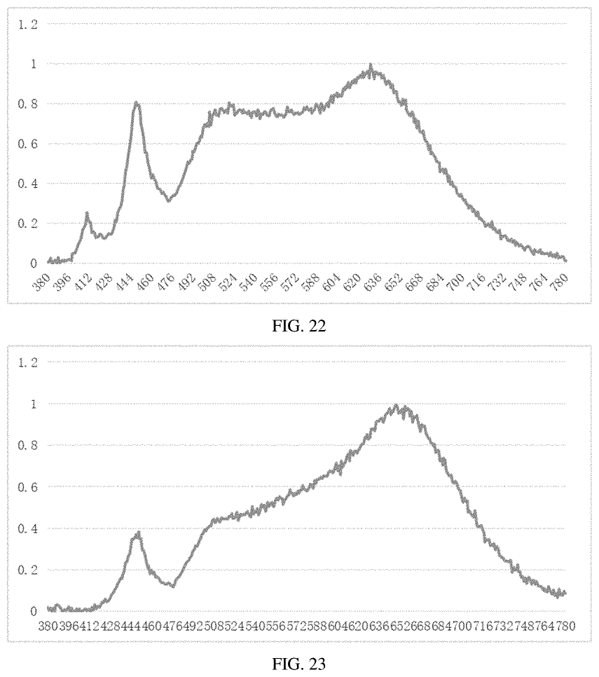

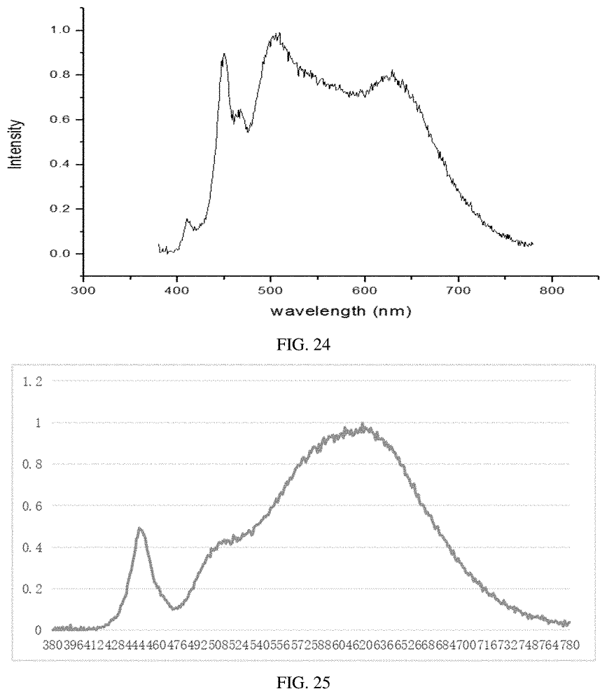

The spectrum dimming packaging bodies of embodiment 5 to embodiment 8 were packaged by COB method. And test results of packaging bodies of embodiment 5 to embodiment 8 and a conventional 1919 COB packaging body having a color temperature of 4000 K were shown in Table 6 herein after (the number of the packaging bodies were 10 in each sample). FIG. 22 to FIG. 25 were spectra of the spectrum dimming packaging bodies packaged by COB method in embodiment 5 to embodiment 8.

TABLE 6
test results of packaging bodies of embodiment 5 to embodiment 8 and a conventional packaging body

| | | | | | Conventional 1919 |
|---|---|---|---|---|---|
| | Embodiment | Embodiment | Embodiment | Embodiment | COB packaging body |
| | 5 | 6 | 8 | 7 | (4000 K) |
| Interface of the | The emitting surface | The emitting surface | The emitting surface | The emitting surface | The color of the |
| packaging layer | is almost transparent, | is almost transparent, | is almost transparent, | is almost transparent, | emitting surface is |
| | and colors and | and colors and | and colors and | and colors and | dark and turbid |
| | shapes of chips | shapes of chips | shapes of chips | shapes of chips | |
| | inside the packaging | inside the packaging | inside the packaging | inside the packaging | |
| | body can be seen | body can be seen | body can be seen | body can be seen | |
| | clearly | clearly | clearly | clearly | |
| Average Color | 97.1 | 97.0 | 97.5 | 97.3 | 96.1 |
| Rendering Index | | | | | |
| Average luminous | 120 | 110 | 100 | 120 | 92 |
| Efficiency (lm/W) | | | | | |
| Average mass of | 8.1 | 6.7 | 4.5 | 10.0 | >50 |
| blue phosphor (mg) | | | | | |
| Average mass of red | 70.2 | 68.9 | 80.2 | 60.8 | >150 |
| phosphor (mg) | | | | | |
| Average | 93 | 90.8 | 91 | 89.0 | About 95 |
| temperature of a 30 | | | | | |
| W substrate (degree | | | | | |
| centigrade) | | | | | |

It can be concluded from Table 6 and FIG. 22 to FIG. 25 that the chips in the packaging layer of the packaging body in the present disclosure can be seen clearly, preventing the short-wavelength fluorescence generated by exciting the short-wavelength phosphor from being absorbed again by the long-wavelength phosphor. Therefore, the luminous efficiencies of most of the light sources were improved by more than 7%, and the heat dissipation was good. The fluorescence band spectrum was broader and the color rending index improved a little. A color temperature of the packaging body was adjusted by changing a ratio of a number of the red chips to a number of the blue chips. This not only avoided weighing the phosphor with a high precision balance, but also largely decreasing the amount of the phosphor.

### Embodiment 9: Preparing a Spectrum Dimming Packaging Body Having a Color Temperature of 5000 K, which can be Used for Illuminating a Plant

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm. The phosphor in the long-wavelength adhesive layer was phosphor having a wavelength of emitting light of 600 nm. A mass ratio of the long-wavelength phosphor adhesive layer to the glue was 0.2:1. A thickness of the long-wavelength phosphor adhesive layer on the top surface of the second chip was 200 μm, and a thickness of the long-wavelength phosphor adhesive layer on the sidewalls of the second chip was 120 μm.

The third chip was a purple chip or a near-ultraviolet chip having a size of 14 mil×30 mil, and a peak wavelength λC of emitting light of the third chip was 410 nm. The fourth chip was a near-ultraviolet chip having a size of 14 mil×30 mil, and a peak wavelength λD of emitting light of the fourth chip was 380 nm. The phosphor in the short-wavelength adhesive layer was phosphor having a wavelength of emitting light of 480 nm. A mass ratio of the short-wavelength phosphor adhesive layer to the glue was 5:1. The short-wavelength phosphor adhesive layer was covered on a surface of the purple chip and a surface of the near-ultraviolet chip, forming a CSP package. A thickness of the short-wavelength phosphor adhesive layer on the top surface of the purple chip or the near-ultraviolet chip was 400 μm, and a thickness of the short-wavelength phosphor adhesive layer on the sidewalls of the purple chip or the near-ultraviolet chip was 120 μm.

The spectrum dimming packaging body for illuminating the plant could include about 140 chips. Wherein, a number of the first chips was 43, a number of the second chips was 70, a number of the third chips was 9, and a number of the fourth chips was 18. On the CIE chromaticity diagram, a coordinate of the red point corresponding to the second chip was (0.4239, 0.2196). On the CIE chromaticity diagram, a coordinate of the blue point corresponding to the first chip was (0.1631, 0.2457). A coordinate of the mixed point was (0.3103, 0.1819), and a CIE chromaticity diagram coordinate of the color temperature was (0.3453, 0.3542). In the packaging layer of the present embodiment, a weight ratio of the glue was 70%, a weight ratio of the green phosphor was 25% and a weight ratio of the yellow phosphor was 5%.

### Embodiment 10: Preparing a Spectrum Dimming Packaging Body Having a Color Temperature of 4000 K, which can be Used for Illuminating a Plant

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm. The phosphor in the long-wavelength adhesive layer was phosphor having a wavelength of emitting light of 650 nm. A mass ratio of the long-wavelength phosphor adhesive layer to the glue was 2:1. A thickness of the long-wavelength phosphor adhesive layer on the top surface of the second chip was 200 μm, and a thickness of the long-wavelength phosphor adhesive layer on the sidewalls of the second chip was 120 μm.

The third chip was a purple chip or a near-ultraviolet chip having a size of 14 mil×30 mil, and a peak wavelength λC of emitting light of the third chip was 410 nm. The phosphor in the short-wavelength adhesive layer was phosphor having a wavelength of emitting light of 480 nm. A mass ratio of the short-wavelength phosphor adhesive layer to the glue was 1.7:1. The short-wavelength phosphor adhesive layer was covered on a surface of the purple chip, forming a WLP package. A thickness of the short-wavelength phosphor adhesive layer on the top surface of the purple chip was 400 μm, and a thickness of the short-wavelength phosphor adhesive layer on the sidewalls of the purple chip was 0 μm.

The fourth chip was a near-ultraviolet chip having a size of 14 mil×30 mil, and a peak wavelength λD of emitting light of the fourth chip was 380 nm. In the present embodiment, the near-ultraviolet chip was provided without a blue phosphor adhesive layer.

The spectrum dimming packaging body for illuminating the plant could include about 140 chips. Wherein, a number of the first chips was 34, a number of the second chips was 80, a number of the third chips was 8, and a number of the fourth chips was 18. On the CIE chromaticity diagram, a coordinate of the red point corresponding to the second chip was (0.4509, 0.2447). On the CIE chromaticity diagram, a coordinate of the blue point corresponding to the first chip was (0.163, 0.2441). A coordinate of the mixed point was (0.3557, 0.1774), and a CIE chromaticity diagram coordinate of the color temperature was (0.378, 0.364). In the packaging layer of the present embodiment, a weight ratio of the glue was 65%, a weight ratio of the green phosphor was 26% and a weight ratio of the yellow phosphor was 14%.

### Embodiment 11: Preparing a Spectrum Dimming Packaging Body Having a Color Temperature of 3000 K, which can be Used for Illuminating a Plant

The first chip was a blue chip having a size of 14 mil×30 mil, and a peak wavelength λA of emitting light of the first chip was 452 nm.

The second chip was a blue chip having a size of 14 mil×30 mil, and a peak wavelength λB of emitting light of the second chip was 465 nm. The phosphor in the long-wavelength adhesive layer was a mixture of a phosphor having a wavelength of emitting light of 677 nm and a phosphor having a wavelength of emitting light of 850 nm, wherein a mass ratio of the phosphor having a wavelength of emitting light of 677 nm to a phosphor having a wavelength of emitting light of 850 nm was 1:1. A mass ratio of the long-wavelength phosphor adhesive layer to the glue was 5:1. A thickness of the long-wavelength phosphor adhesive layer on the top surface of the second chip was 200 μm, and a thickness of the long-wavelength phosphor adhesive layer on the sidewalls of the second chip was 120 μm.

The third chip was a purple chip or a near-ultraviolet chip having a size of 14 mil×30 mil, and a peak wavelength λC of emitting light of the third chip was 410 nm. The phosphor in the short-wavelength adhesive layer was phosphor having a wavelength of emitting light of 480 nm. A mass ratio of the short-wavelength phosphor adhesive layer to the glue was 0.2:1. The short-wavelength phosphor adhesive layer was covered on a surface of the purple chip, forming a WLP package. A thickness of the short-wavelength phosphor adhesive layer on the top surface of the purple chip was 200 μm, and a thickness of the short-wavelength phosphor adhesive layer on the sidewalls of the purple chip was 0 μm.

The fourth chip was a near-ultraviolet chip having a size of 14 mil×30 mil, and a peak wavelength λD of emitting light of the fourth chip was 380 nm. In the present embodiment, the near-ultraviolet chip was provided without a blue phosphor adhesive layer.

The spectrum dimming packaging body for illuminating the plant included about 200 chips. Wherein, a number of the first chips was 25, a number of the second chips was 150, a number of the third chips was 7, and a number of the fourth chips was 18. On the CIE chromaticity diagram, a coordinate of the red point corresponding to the second chip was (0.4852, 0.2883). On the CIE chromaticity diagram, a coordinate of the blue point corresponding to the first chip was (0.1621, 0.2432). A coordinate of the mixed point was (0.4001, 0.2103), and a CIE chromaticity diagram coordinate of the color temperature was (0.4367, 0.4043). In the packaging layer of the present embodiment, a weight ratio of the glue was 60%, a weight ratio of the green phosphor was 28% and a weight ratio of the yellow phosphor was 12%.

The packaging bodies in embodiment 9 to embodiment 11 were packaged by COB method, and compared with a packaging body in the conventional art. The test results were shown in Table 7 hereinafter (the number of the packaging bodies were 12 in each sample).

TABLE 7
test results of packaging bodies of embodiments 9 to 11 and conventional packaging bodies

| | | | | A packaging body | |
|---|---|---|---|---|---|
| | | | | for plant lamination | Conventional 1919 |
| | Embodiment 9 | Embodiment 10 | Embodiment 11 | XX-351B (4000 K | COB packaging |
| | (5000 K) | (4000 K) | (3000 K) | SMD) | (4000 K) |
| Interface of the | The emitting surface | The emitting surface | The emitting surface | The color of the | The color of the |
| packaging layer | is almost transparent, | is almost transparent, | is almost transparent, | emitting surface is | emitting surface is |
| | and colors and | and colors and | and colors and | dark and turbid. | dark and turbid. |
| | shapes of chips | shapes of chips | shapes of chips | | |
| | inside the packaging | inside the packaging | inside the packaging | | |
| | body can be seen | body can be seen | body can be seen | | |
| | clearly. | clearly. | clearly. | | |
| Average Color | 97.0 | 96.9 | 96.8 | 80 | 96.1 |
| Rendering Index | | | | | |
| Average mass of | 8.1 | 6.7 | 10.0 | / | >50 |
| blue phosphor (mg) | | | | | |
| Average mass of red | 70.2 | 68.9 | 60.8 | / | >150 |
| phosphor (mg) | | | | | |
| Luminous Flux at 85 | 129 lm | 132 lm | 136 lm | 145 lm | 135 lm |
| degree centigrade (by | | | | | |
| current method) | | | | | |
| Junction | 95 | 95 | 93 | 114 | 110 |
| Temperature | | | | | |
| (degree centigrade) | | | | | |

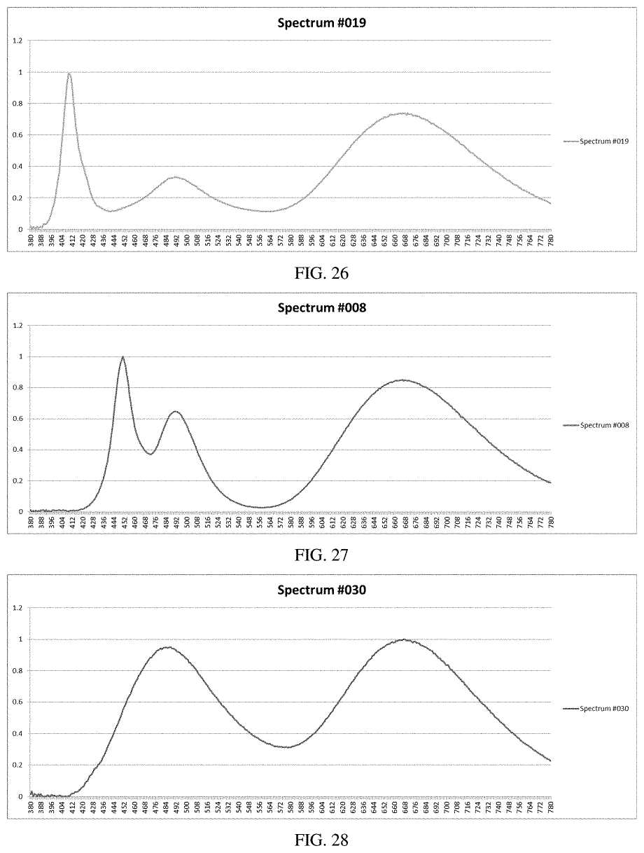

FIG. 26 to FIG. 28 were spectra of the spectrum dimming packaging bodies packaged by COB method in embodiment 9 to embodiment 11, and the wave band distribution of the embodiments were shown in Table 8 hereinafter.

TABLE 8
emission spectrum bands of embodiment 9 to embodiment 11

| Wave band | Embodiment 9 | Embodiment 10 | Embodiment 11 |
|---|---|---|---|
| (nm) | (5000 K) | (4000 K) | (3000 K) |
| 380-430 | Having emitting | / | / |
| | light having a | | |
| | peak wavelength | | |
| | of 412 nm | | |
| 430-470 | / | Having emitting | Having mission |
| | | light having a | light |
| | | peak wavelength | |
| | | of 450 nm | |
| 470-520 | Having emitting | Having emitting | Having emitting |
| | light having a | light having a | light having a |
| | peak wavelength | peak wavelength | peak wavelength |
| | of 485 nm | of 492 nm | of 485 nm |
| 520-550 | / | / | Having mission |
| | | | light |
| 600-1000 | Having emitting | Having emitting | Having emitting |
| | light having a | light having a | light having a |
| | peak wavelength | peak wavelength | peak wavelength |
| | of 670 nm | of 668 nm | of 670 nm |

It can be concluded from Table 8 and FIG. 26 to FIG. 28 that the chips in the packaging layer of the packaging body in the present disclosure can be seen clearly, and the color rendering indexes were largely improved. The packaging body not only can satisfy requirements for illuminating the plant, but also have relatively high color rendering index and can be used for indoor or outdoor lighting. However, the luminous flux decreased a little. Moreover, a color temperature of the packaging body was adjusted by changing a ratio of a number of the red chips to a number of the blue chips. This not only avoided weighing the phosphor with a high precision balance, but also largely decreasing the amount of the phosphor.

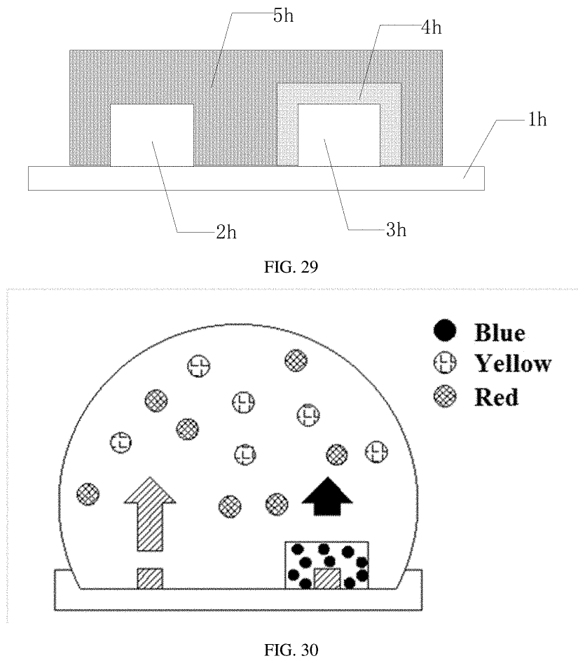

Referring to FIG. 29, FIG. 29 is a structural schematic diagram of a packaging body in another embodiment of the present disclosure. The packaging body can include a support member 1h, at least one first chip 2h, at least one second chip 3h and a packaging layer 5h. Wherein, the support member 1h can be any one selected from a substrate with a circuit, a support frame with a circuit and an adhesive membrane without a circuit. The first chip 2h and the second chip 3h can be located on a surface of the support member 1h. Compared with the embodiments above, at least a top surface of the second chip 3h can be provided with a blue phosphor adhesive layer 4h. A packaging layer 5h can cover the surface of the support member 1h. The first chip 2h, the second chip 3h and the blue phosphor adhesive layer 4h can be located in the packaging layer 5h. The packaging layer 5h can be a first phosphor adhesive layer that does not contain a blue phosphor. A peak wavelength L₁ of a phosphor in the first phosphor adhesive layer can be greater than a peak wavelength L_{blue} of the blue phosphor in the blue phosphor adhesive layer 4h.

In the present embodiment, a peak wavelength of the first chip can be identified as λA, which can be in a range of 445 nm to 550 nm, and a peak wavelength of the second chip can be identified as λB, which can be in a range of 390 nm to 430 nm. The phosphor in the first phosphor adhesive layer in the packaging layer 5h can be one or more selected from a green phosphor, a yellow phosphor and a red phosphor, and the peak wavelength L₁ of emitting light of the phosphor in the first phosphor adhesive layer can be in a range of 505 nm to 900 nm. The phosphor in the blue phosphor adhesive layer can be one or more selected from a blue phosphor and an indigo phosphor, and the peak wavelength L_{blue} of the blue phosphor in the blue phosphor adhesive layer can be in a range of 450 nm to 505 nm.

It should be noted that a number of the first chips 2h and a number of the second chips 3h are not limited to one. The number of the first chips 2h and the number of the second chips 3h can be increased according to requirements of an actual luminescence spectrum.

FIG. 30 is a structural schematic diagram of an excitation mode of the packaging body. The packaging body will be illustrated in detail in conjunction with some embodiments hereinafter. The packaging bodies packaged by SMD method and COB method were taken as examples. A blue phosphor adhesive layer 4h was disposed on the top surface and sidewalls of the second chip 3h. The first chip 2h was an LED chip which emitted a light having a wavelength of 445 nm. The second chip 3h was a LED chip which emitted a light having a wavelength of 430 nm. A phosphor in the blue phosphor adhesive layer 4h was a blue phosphor, and a peak wavelength of emitting light of the blue phosphor was 450 nm. A phosphor in the packaging layer 5h that did not contain a blue phosphor was a mixed phosphor consisted of a yellow phosphor and a red phosphor, and a peak wavelength of emitting light of the mixed phosphor was 710 nm.

The packaging bodies packaged by SMD method were tested and compared with a sample purchased from the marked, and the test results were shown in Table 9.

TABLE 9
test results of two samples packaged by SMD method

| | Forward | Forward | Power | Luminous | Luminous | Chromaticity | Chromaticity | Color |
|---|---|---|---|---|---|---|---|---|
| | current | Voltage | P | Flux | Efficiency | Coordinate | Coordinate | Temperature |
| Sample | I_{F} (mA) | V_{F} (V) | (W) | Φ (lm) | (lm/W) | X | Y | Tc (K) |
| Convention | 149.9 | 3.3 | 494.6 | 48.6 | 98.26 | 0.3294 | 0.3362 | 5643 |
| SMD | | | | | | | | |
| packaging body | | | | | | | | |
| SMD | 59.9 | 8.832 | 529 | 55.6 | 105.1 | 0.3677 | 0.388 | 4427 |
| packaging body | | | | | | | | |
| of the present | | | | | | | | |
| embodiment | | | | | | | | |

It can be concluded from the test results that when the light source areas were the same, the light sources containing the packaging bodies packaged by SMD method in the present embodiment had greater luminous efficiency.

The packaging bodies packaged by COB method were tested and compared with a sample purchased from the marked, and the test results were shown in Table 10.

TABLE 10
test results of two samples packaged by COB method

| | Forward | Forward | Power | Luminous | Luminous | Chromaticity | Chromaticity | Color | Color |
|---|---|---|---|---|---|---|---|---|---|
| | current | Voltage | P | Flux | Efficiency | Coordinate | Coordinate | rendering | Temperature |
| Sample | I_{F} (mA) | V_{F} (V) | (W) | Φ (lm) | (lm/W) | X | Y | index | Tc (K) |
| Conventional | 1000 | 33 | 33 | 2950 | 89.4 | 0.3510 | 0.3561 | 90.6 | 4801 |
| COB | | | | | | | | | |
| packaging | | | | | | | | | |
| body | | | | | | | | | |
| COB | 1001 | 36.28 | 36.3 | 3532 | 97.29 | 0.3507 | 0.3675 | 95.5 | 4858 |
| packaging | | | | | | | | | |
| body of the | | | | | | | | | |
| present | | | | | | | | | |
| embodiment | | | | | | | | | |

It can be concluded from the test results that when the light source areas were the same, the light sources containing the packaging bodies packaged by COB method in the present embodiment had greater luminous efficiency.

In the packaging body of the embodiments of the present disclosure, chips having different emission wavelengths are used, therefore phosphors having different excitation wavelengths can be excited. That is, a short-wavelength fluorescence emitted from a short-wavelength chip can excite a short-wavelength phosphor, and a long-wavelength fluorescence emitted from a long-wavelength chip can excite a long-wavelength phosphor. Meanwhile, a short-wavelength fluorescence emitted by the short-wavelength phosphor will not excite the long-wavelength phosphor and be consumed again. Therefore, optimal quantum yield can be achieved and luminous efficiency of a light source can be improved via choosing an optimal excitation wavelength. Furthermore, chips having different emission wavelengths are packaged by different methods, respectively. Compared with the conventional art, the blue phosphor is packaged in local areas such as a top surface and sidewalls of a chip by CSP method or WLP method, and only a small amount of short-wavelength fluorescence and medium-wavelength fluorescence can illuminate on the blue phosphor. This can effectively prevent red fluorescence and green fluorescence from being absorbed again by the blue phosphor. For cyan light having low excitation efficiency, the method in the present disclosure can effectively reduce secondary loss of cyan fluorescence and improve the luminous efficiency while improving color rendering index. Moreover, according to Stokes shift, for one phosphor, a wavelength of an emitting light will shift along with shift of a wavelength of an excitation light. Therefore, in the present disclosure, a cyan fluorescence having a relatively short wavelength can be obtained by exciting a cyan phosphor with a short-wavelength fluorescence emitted by a short-wavelength chip; a blue fluorescence having a relatively short wavelength can be obtained by exciting a blue phosphor with a short-wavelength fluorescence emitted by a short-wavelength chip; and a green fluorescence having a relatively short wavelength can be obtained by exciting a green phosphor with a short-wavelength fluorescence emitted by a short-wavelength chip. Therefore, a fluorescence band spectrum of a packaging body can be broader, and the color rendering index can be further improved. Finally, in the present disclosure, a color temperature of the packaging body can be adjusted by changing a ratio of the number of the red chips to the number of the blue chips. In the conventional art, the color temperature of a light source is changed by adjusting an amount of a red phosphor or other phosphors in the entire phosphor layer, but this may result in an emitting surface packaged by COB method being dark and turbid. Besides, in the conventional art, the phosphor needs to be accurately weighted with a high precision balance to change the color temperature. However, in the present disclosure, the chips are packaged by CSP method, respectively. Therefore, the color temperature can be changed by adjusting the ratio of the number of the red chips to the number of the blue chips.

What is claimed is:

1. A packaging body, comprising,
a support member;
at least one first chip and at least one second chip, the at least one first chip and the at least one second chip being located on a surface of the support member, and at least a top surface of the at least one second chip being provided with a long-wavelength phosphor adhesive layer; and,
a packaging layer covering the surface of the support member,
wherein the at least one first chip, the at least one second chip, and the long-wavelength phosphor adhesive layer are located in the packaging layer,
the packaging layer is a first phosphor adhesive layer that does not comprise a long-wavelength phosphor,
and a peak wavelength L₁ of emitting light of a phosphor in the first phosphor adhesive layer is less than a peak wavelength L_{red} of emitting light of the long-wavelength phosphor.

2. The packaging body of claim 1, wherein
a peak wavelength of emitting light of the at least one first chip is identified as λA₁, which is in a range of 390 nm to 460 nm, a peak wavelength of emitting light of the at least one second chip is identified as λB₁, which is in a range of 445 nm to 550 nm, and the peak wavelength λA₁ of emitting light of the at least one first chip and the peak wavelength of emitting light λB₁ of the at least one second chip satisfy a formula as follow: 0≤λB₁−λA₁≤160 nm, and/or,
the phosphor in the first phosphor adhesive layer is one or more selected from a green phosphor, an indigo phosphor, a cyan phosphor, a yellow phosphor and a blue phosphor, and the peak wavelength L₁ of emitting light of the phosphor in the first phosphor adhesive layer is in a range of 470 nm to 590 nm.

3. The packaging body of claim 1, wherein
at least the top surface of the at least one first chip is provided with a second phosphor adhesive layer that does not contain a red phosphor, and the second phosphor adhesive layer is located in the packaging layer; and, a peak wavelength L₂ of a phosphor in the second phosphor adhesive layer is less than the peak wavelength L₁ of emitting light of the phosphor in the first phosphor adhesive layer.

4. The packaging body of claim 3, wherein
a peak wavelength of emitting light of the at least one first chip is identified as λA₂, in a range of 390 nm to 445 nm, and a peak wavelength of emitting light of the at least one second chip is identified as λB₂, in a range of 445 nm to 550 nm, and the peak wavelength λA₂ of emitting light of the at least one first chip and the peak wavelength λB₂ of emitting light of the at least one second chip satisfy a formula as follow: 5≤λB₂−λA₂≤160 nm; and/or,
the phosphor in the first phosphor adhesive layer is one or more selected from a green phosphor and a yellow phosphor, and the peak wavelength L₁ of emitting light of the phosphor in the first phosphor adhesive layer is in a range of 510 nm to 590 nm; and the phosphor in the second phosphor adhesive layer is one or more selected from a green phosphor, an indigo phosphor, a cyan phosphor, a yellow phosphor and a blue phosphor, and peak wavelength L₂ of a phosphor in the second phosphor adhesive layer is in a range of 470 nm to 590 nm.

5. The packaging body of claim 3, wherein
at least one third chip is disposed at the surface of the supporting member, and the at least one third chip is located in the packaging layer,
a peak wavelength of emitting light of the at least one first chip is identified as λA₃, which is in a range of 390 nm to 445 nm, a peak wavelength of emitting light of the third chip is identified as λC₃, which is in a range of 420 nm to 465 nm, and a peak wavelength of emitting light of the at least one second chip is identified as λB₃, which is in a range of 445 nm to 550 nm,
the peak wavelength λA₃ of emitting light of the at least one first chip, the peak wavelength λC₃ of emitting light of the third chip and the peak wavelength of emitting light λB₃ of the at least one second chip satisfy formulas as follow: 0≤λB₃−λC₃≤130 nm and 15≤λC₃−λA₃≤130 nm.

6. The packaging body of claim 5, wherein
the phosphor in the first phosphor adhesive layer is one or more selected from a green phosphor, and a yellow phosphor, and the peak wavelength L₁ of emitting light of the phosphor in the first phosphor adhesive layer is in a range of 510 nm to 590 nm; and the phosphor in the second phosphor adhesive layer is one or more selected from an indigo phosphor, a cyan phosphor and a blue phosphor, and the peak wavelength L₂ of a phosphor in the second phosphor adhesive layer is in a range of 470 nm to 510 nm.

7. The packaging body of claim 5, wherein
at least a top surface of the third chip is provided with a third phosphor adhesive layer that does not contain a red phosphor, and the packaging layer further covers the third phosphor adhesive layer; and, a peak wavelength L₃ of a phosphor in the third phosphor adhesive layer is greater than the peak wavelength L₂ of emitting light of the phosphor in the second phosphor adhesive layer; and less than the peak wavelength L₁ of emitting light of the phosphor in the first phosphor adhesive layer; and/or,
at least one fourth chip is disposed at the side disposing the at least one first chip of the supporting member, a peak wavelength of the fourth chip is identified as λD, which is in a range of 420 nm to 465 nm, and the packaging layer further covers the fourth chip, and/or,
the phosphor in the first phosphor adhesive layer is one or more selected from a green phosphor and a yellow phosphor, and the peak wavelength L₁ of emitting light of the phosphor in the first phosphor adhesive layer is in a range of 530 nm to 590 nm; the phosphor in the second phosphor adhesive layer is one or more selected from an indigo phosphor, a cyan phosphor and a blue phosphor, and the peak wavelength L₂ of the phosphor in the second phosphor adhesive layer is in a range of 470 nm to 510 nm; and the phosphor in the third phosphor adhesive layer is a green phosphor, and the peak wavelength L₃ of the phosphor in the third phosphor adhesive layer is in a range of 510 nm to 540 nm, and/or,
the at least one first chip is a purple LED chip having a peak wavelength in a range of 390 nm to 430 nm, and the phosphor in the second phosphor adhesive layer is the blue phosphor.

8. The packaging body of claim 1, wherein
a peak wavelength of emitting light of the at least one first chip is identified as λA₄, which is in a range of 420 nm to 465 nm, a peak wavelength of emitting light of the at least one second chip is identified as λB₄, which is in a range of 445 nm to 550 nm, and the peak wavelength λA₄ of emitting light of the at least one first chip and the peak wavelength λB₄ of emitting light of the at least one second chip satisfy a formula as follow: 0≤λB₄−λA₄≤130 nm.

9. The packaging body of claim 8, wherein
the long-wavelength phosphor adhesive layer comprises a glue and the long-wavelength phosphor having a emission wavelength in a range of 600 nm to 1000 nm;
a weight ratio of the long-wavelength phosphor to a glue is in a range of 0.2:1 to 5:1; and/or,
the first phosphor adhesive layer comprises at least one of a green phosphor having an emission wavelength in a range of 500 nm to 550 nm and a yellow phosphor having an emission wavelength in a range of 550 nm to 600 nm, and does not comprise a blue phosphor having an emission wave length in a range of 450 nm to 500 nm or a long-wavelength phosphor having an emission wavelength in a range of 600 nm to 1000 nm.

10. The packaging body of claim 9, wherein the packaging body comprises a plurality of first chips and a plurality of second chips,
when a color temperature of the packaging body in entirety is greater than 4500 K, a number of the plurality of second chips accounts for 5% to 30% in a sum of the number of the plurality of first chips and a number of the plurality of second chips; and
when the color temperature of the entire packaging body is equal to or less than 4500 K, a number of the second chip accounts for 30% to 80% in a total number of the plurality of first chips and the second chip.

11. The packaging body of claim 9, wherein
the long-wavelength phosphor adhesive layer is disposed on the top surface and sidewalls of the second chip, forming a CSP packaging structure, or the long-wavelength phosphor adhesive layer is disposed the top surface of the second chip, forming a WLP packaging structure,
a thickness of the long-wavelength phosphor adhesive layer on the top surface of the second chip is in a range of 20 μm to 400 μm, and a thickness of the long-wavelength phosphor adhesive layer on the sidewalls of the second chip is in a range of 0 to 400 μm; and
the long-wavelength phosphor having the emission wavelength in a range of 600 nm to 1000 nm comprises one or two of a red phosphor and a near infrared phosphor.

12. The packaging body of claim 14, wherein
the long-wavelength phosphor comprises a red phosphor having an emission wavelength in a range of 658 nm to 660 nm, and the red phosphor having an emission wavelength in a range of 658 nm to 660 nm accounts for 50% or above of a weight of the long-wavelength phosphor; and/or
the long-wavelength phosphor comprises a red phosphor having an emission wavelength in a range of 605 nm to 630 nm and does not comprises a phosphor having an emission wavelength greater than 630 nm.

13. The packaging body of claim 8, wherein
at least one third chip is disposed at the surface of the supporting member, the third chip is a purple chip or a near ultraviolet chip,
a peak wavelength of an emitting light of the third chip is identified as λC₄₁, which is in a range of 370 nm to 420 nm,
a first short-wavelength phosphor adhesive layer is disposed on a surface of the third chip, and the first short-wavelength phosphor adhesive layer comprises a glue and the short-wavelength phosphor;
a weight ratio of a first short-wavelength phosphor in the first short-wavelength phosphor adhesive layer to a glue is in a range of 0.2:1 to 5:1, and/or
the packaging body comprises a plurality of first chips and a plurality of third chips, a ratio of a number of the plurality of third chips to a number of the plurality of first chips is in a range of 1:1 to 1:5; and/or,
a weight ratio of the short-wavelength phosphor in the first short-wavelength phosphor adhesive layer to a glue is in a range of 2:1 to 5:1; and
a ratio of the number of the plurality of third chips to the number of the plurality of first chips is in a range of 1:1 to 1:3, and/or,
the first short-wavelength phosphor adhesive layer is disposed on the top surface and sidewalls of the at least one of the second chip, forming a CSP packaging structure with sidewalls of the second chip, or,
the first short-wavelength phosphor adhesive layer is disposed the top surface of the at least one of the second chip, forming a WLP packaging structure,
a thickness of the first short-wavelength phosphor adhesive layer on the top surface of the at least one of the second chip is in a range of 20 μm to 400 μm, and a thickness of the first short-wavelength phosphor adhesive layer on the sidewalls of the at least one of the second chip is in a range of 0 to 400 μm.

14. The packaging body of claim 8, wherein
at least one third chip and at least one fourth chip is disposed at the surface of the supporting member,
the at least one third chip is a purple chip, and a second short-wavelength phosphor adhesive layer is disposed on a surface of the third chip; a peak wavelength of emitting light of the third chip is identified as λC₄₂, which is in a range of 400 nm to 420 nm,
the at least one fourth chip is a purple chip or a near ultraviolet chip, a peak wavelength of emitting light of the fourth chip is identified as λD₄₂, which is in a range of 370 nm to 400 nm, and a third short-wavelength phosphor adhesive layer is disposed on the surface of the fourth chip, or the at least one fourth chip is provided without the third short-wavelength phosphor adhesive layer;
the second short-wavelength phosphor adhesive layer disposed on the at least one third chip and the third short-wavelength phosphor adhesive layer disposed on the at least one fourth chip comprises a glue and a blue phosphor having an emission wavelength in a range of 450 nm to 500 nm,
a weight ratio of the blue phosphor in the second short-wavelength phosphor adhesive layer or the third short-wavelength phosphor adhesive layer to a glue is in a range of 0.2:1 to 5:1; and/or
a number of the at least one of the second chip accounts for 50% to 75% in a total number of the at least one of the first chip, the at least one of the second chip, the at least one of the third chip and the at least one of the fourth chip; and/or
a ratio of a number of the at least one of the third chip to a number of the at least one of the fourth chip is in a range of 1:1 to 1:3; and/or
a ratio of a number of the at least one of the first chip to a sum number of the at least one of the third chip and at least one of the fourth chip is in a range of 2:2 to 2:0.5, and/or,
the short-wavelength phosphor adhesive layer is disposed on the top surface and sidewalls of the at least one of the second chip, forming a CSP packaging structure with sidewalls of the second chip, or,
the short-wavelength phosphor adhesive layer is disposed the top surface of the at least one of the second chip, forming a WLP packaging structure,
a thickness of the short-wavelength phosphor adhesive layer on the top surface of the at least one of the second chip is in a range of 20 μm to 400 μm, and a thickness of the short-wavelength phosphor adhesive layer on the sidewalls of the at least one of the second chip is in a range of 0 to 400 μm;

15. The packaging body of claim 1, wherein
the support member is any one selected from a substrate with a circuit, a support frame with a circuit and an adhesive membrane without a circuit.

16. A method for preparing a packaging body, comprising:
step S1, providing at least one first chip and at least one second chip, wherein a long-wavelength phosphor adhesive layer is disposed on at least a top surface of the at least one second chip;
step S2, designing a ratio of a number of the at least one second chip to a total number of the at least one first chip and the at least one second chip according to a preset color temperature of a packaging body product, defining a chromaticity coordinate of the at least one second chip on a CIE chromaticity diagram according to the ratio of the number of the at least one second chip to the total number of the at least one first chip and the at least one second chip as a red point (X1, Y1), and defining a chromaticity coordinate of the at least one first chip on the CIE chromaticity diagram according to the ratio of the number of the at least one first chip to the total number of the at least one first chip and the at least one second chip as a blue point (X2, Y2);
step S3 of pre-controlling the color temperature, comprising:
fixing the at least one first chip and the at least one second chip to corresponding positions on a support member, respectively;
making the at least one first chip and the at least one second chip emit light, and looking up a chromaticity coordinate of the lighted at least one first chip and the lighted least one second chip on the CIE chromaticity diagram, wherein the chromaticity coordinate of the lighted at least one first chip and lighted least one second chip is identified as a mixed point (X3, Y3);
ensuring that the Y3 in mixed point (X3, Y3) is greater than or equal to 0.08 and less than or equal to 0.30, and the X3 in mixed point (X3, Y3) is greater than or equal to 0.22 and less than or equal to 0.43, thereby pre-controlling a range of the color temperature; and
if the Y3 in mixed point (X3, Y3) is not greater than or equal to 0.08 and less than or equal to 0.30, and the X3 in mixed point (X3, Y3) is not greater than or equal to 0.22 and less than or equal to 0.43, repeating step S2;
step S4, looking up a chromatic coordinate of the preset color temperature of the packaging body product along the Planckian locus on the CIE chromaticity diagram according to requirements of the present color temperature of the packaging body product, and identifying the chromaticity coordinate of the preset color temperature of the packaging body product as a white point (X4, Y4); obtaining a specific chromatic coordinate or a range of chromatic coordinates of a green point (X5, Y5) according to chromatic coordinates of the red point (X1, Y1), the blue point (X2, Y2), the mixed point (X3, Y3) and the white point (X4, Y4); selecting a suitable first phosphor according to the chromatic coordinate of the green point, and mixing the first phosphor with a glue to form a first phosphor adhesive layer; entirely packaging the at least one first chip and the at least one second chip on the supporting member with the first phosphor adhesive layer to form a packaging layer; and heating and solidifying to obtain the packaging body product; and
step S5, detecting a luminescence spectrum and the color temperature of the packaging body product,
wherein if a chromatic coordinate of the packaging body product is different from that along the Planckian locus, adjusting constituents of the first phosphor in the packing layer;
if the color temperature does not conform to the preset color temperature, adjusting the ratio of the number of the at least one second chip to the total number of the at least one first chip and the at least one second chip, and repeating the steps S3 to S5.

17. The method of claim 16, wherein
a peak wavelength of emitting light of the at least one first chip is identified as λA₅, which is in a range of 420 nm to 465 nm, and a peak wavelength of emitting light of the at least one second chip is identified as λB₅, which is in a range of 445 nm to 550 nm, the peak wavelength λA₅ of emitting light of the at least one first chip and the peak wavelength λB₅ of emitting light of the at least one second chip satisfy with a formula as follows: 0≤λB₅−λA₅≤130 nm;
the step S3 further comprises: ensuring that the Y3 is greater than or equal to 0.08 and less than or equal to 0.20, and the X3 is greater than or equal to 0.22 and less than or equal to 0.43; or,
in the step S4, selecting the suitable first phosphor comprises selecting a green phosphor having an emission wavelength in a range of 500 nm to 550 nm and a yellow phosphor having an emission wavelength in a range of 550 nm to 600 nm with a suitable weight ratio as the suitable first phosphor; and,
in step S5, if a vertical coordinate of the chromatic coordinate of the packaging body product is greater than that along the Planckian locus on the CIE chromaticity diagram, adding a green phosphor into the first phosphor, and if the vertical coordinate of the chromatic coordinate of the packaging body product is less than that along the Planckian locus on the CIE chromaticity diagram, adding a yellow phosphor into the first phosphor.

18. The method of claim 16, wherein
a peak wavelength of emitting light of the at least one first chip is identified as λA₆, which is in a range of 420 nm to 465 nm, and a peak wavelength of emitting light of the least one second chip is identified as λB₆, which is in a range of 445 nm to 550 nm,
the step S1 further comprises:
providing a third chip, which is a purple chip or a near ultraviolet chip, wherein a peak wavelength of emitting light of the third chip is identified as λC₆ in a range of 370 nm to 420 nm, and disposing a fourth short-wavelength phosphor adhesive layer on a surface of the third chip;
wherein the step S3 further comprises: ensuring that the Y3 is greater than or equal to 0.09 and less than or equal to 0.20, and the X3 is greater than or equal to 0.22 and less than or equal to 0.37;
the step S5 further comprises: if the luminescence spectrum does not meet preset requirements of the packaging body product, adjusting a number of the third chip and repeating the steps S3 to S5.

19. The method of claim 16, wherein
a peak wavelength of emitting light of the at least one first chip is identified as λA₇ in a range of 420 nm to 465 nm, and a peak wavelength of emitting light of the least one second chip is identified as λB₇ in a range of 445 nm to 550 nm,
the step S1 further comprises:
providing a third chip and a fourth chip, wherein the third chip is a purple chip with a fifth short-wavelength phosphor adhesive layer disposed on a surface of the purple chip, and the fourth chip is a near ultraviolet chip with or without a sixth short-wavelength phosphor adhesive layer,
wherein the step S3 further comprises: ensuring that the Y3 is greater than or equal to 0.16 and less than or equal to 0.30, and the X3 is greater than or equal to 0.28 and less than or equal to 0.42; and
the step S5 further comprises: if the luminescence spectrum does not meet preset requirements of the packaging body product, adjusting the number of the at least one first chip, a number of the third chip and a number of the fourth chip, and repeating the steps S3 to S5.

20. A packaging body, comprising:
a support member;
at least one first chip and at least one second chip, wherein the at least one first chip and the least one second chip are located on a surface of the support member, and at least a top surface of the least one second chip is provided with a blue phosphor adhesive layer; and
a packaging layer covering the surface of the support member,
wherein the at least one first chip, the at least one second chip, and the blue phosphor adhesive layer are located in the packaging layer,
the packaging layer is a first phosphor adhesive layer that does not contain a blue phosphor,
and a peak wavelength L₁ of a phosphor in the first phosphor adhesive layer is greater than a peak wavelength L_{blue} of the blue phosphor in the blue phosphor adhesive layer; and/or,
a peak wavelength of the at least one first chip is identified as λA₈, which is in a range of 445 nm to 550 nm, and a peak wavelength of at the least one second chip is identified as λB₈, which is in a range of 390 nm to 430 nm;
the phosphor in the first phosphor adhesive layer is one or more selected from a green phosphor, a yellow phosphor and a red phosphor, and the peak wavelength L₁ of emitting light of the phosphor in the first phosphor adhesive layer is in a range of 505 nm to 900 nm; and
the phosphor in the blue phosphor adhesive layer is one or more selected from a blue phosphor and a indigo phosphor, and the peak wavelength L_{blue} of the blue phosphor in the blue phosphor adhesive layer is in a range of 450 nm to 505 nm.
